(19) United States
(12) Patent Application Publication
(10) Pub. No.: US 2013/0233383 A1
(43) Pub. Date: Sep. 12, 2013

(54) Electronic Device Module Comprising Film of Homogeneous Polyolefin Copolymer and Grafted Silane

(71) Applicants: John A. Naumovitz, Midland, MI (US); Rajen M. Patel, Lake Jackson, TX (US); Shaofu Wu, Sugar Land, TX (US); Debra H. Neimann, Lake Jackson, TX (US)

(72) Inventors: John A. Naumovitz, Midland, MI (US); Rajen M. Patel, Lake Jackson, TX (US); Shaofu Wu, Sugar Land, TX (US); Debra H. Neimann, Lake Jackson, TX (US)

(21) Appl. No.: 13/701,534

(22) PCT Filed: Jun. 6, 2011
(86) PCT No.: PCT/US11/39307

§ 371 Date: Jan. 9, 2013

Related U.S. Application Data
(60) Provisional application No. 61/351,577, filed on Jun. 4, 2010.

(51) Int. Cl. H01L 31/0203; H01L 23/29

(52) U.S. Cl. CPC H01L 31/0203; H01L 23/293
USPC 136/259; 257/791

(57) ABSTRACT

An electronic device module comprising:
A. At least one electronic device, e.g., a solar cell, and
B. A polymeric material in intimate contact with at least one surface of the electronic device, the polymeric material comprising (1) an ethylene interpolymer comprising an overall polymer density of not more than 0.905 g/cm³; total unsaturation of not more than 125 per 100,000 carbons; up to 3 long chain branches/1000 carbons; vinyl-3 content of less than 5 per 100,000 carbons; and a total number of vinyl groups/1000 carbons of less than the quantity (8000/Mₙ), wherein the vinyl-3 content and vinyl group measurements are measured by gel permeation chromatography (145° C.) and ¹H-NMR (125° C.), (2) grafted vinyl silane, (3) optionally, free radical initiator or a photoinitiator in an amount of at least about 0.05 wt % based on the weight of the copolymer, and (3) optionally, a co-agent in an amount of at least about 0.05 wt % based upon the weight of the copolymer.

### CROSS REFERENCE TO RELATED APPLICATION

This application claims priority from U.S. provisional application Ser. No. 61/351,577, filed Jun. 4, 2010, which is incorporated herein by reference in its entirety. This application is related to U.S. National application Ser. No. 11/857,208 filed Sep. 18, 2007, which claims the benefit of U.S. Ser. No. 60/826,328 filed Sep. 20, 2006; and U.S. Ser. No. 60/865,965 filed Nov. 15, 2006; the disclosures of which are incorporated herein by reference for U.S. prosecution purposes.

### FIELD OF THE INVENTION

This invention relates to electronic device modules. In one aspect, the invention relates to electronic device modules comprising an electronic device, e.g., a solar or photovoltaic (PV) cell, and a protective polymeric material while in another aspect, the invention relates to electronic device modules in which the protective polymeric material is a polymeric material in intimate contact with at least one surface of the electronic device, wherein the copolymer of ethylene and at least one alpha-olefin comprises a grafted silane component to enhance the adhesion and is characterized as having an overall polymer density of not more than 0.905 g/cm³; total unsaturation of not more than 125 per 100,000 carbons; up to 3 long chain branches/1000 carbons; vinyl-3 content of less than 5 per 100,000 carbons; and a total number of vinyl groups/1000 carbons of less than the quantity (8000/Mₙ), wherein the vinyl-3 content and vinyl group measurements are measured by gel permeation chromatography (145° C.) and ¹H-NMR (125° C.). In yet another aspect, the invention relates to a method of making an electronic device module.

### BACKGROUND OF THE INVENTION

Polymeric materials are commonly used in the manufacture of modules comprising one or more electronic devices including, but not limited to, solar cells (also known as photovoltaic cells), liquid crystal panels, electro-luminescent devices and plasma display units. The modules often comprise an electronic device in combination with one or more substrates, e.g., one or more glass cover sheets, often positioned between two substrates in which one or both of the substrates comprise glass, metal, plastic, rubber or another material. The polymeric materials are typically used as the encapsulant or sealant for the module or depending upon the design of the module, as a skin layer component of the module, e.g., a backskin in a solar cell module. Typical polymeric materials for these purposes include silicone resins, epoxy resins, polyvinyl butyral resins, cellulose acetate, ethylene-vinyl acetate copolymer (EVA) and ionomers.

United States Patent Application Publication 2001/0045229 A1 identifies a number of properties desirable in any polymeric material that is intended for use in the construction of an electronic device module. These properties include (i) protecting the device from exposure to the outside environment, e.g., moisture and air, particularly over long periods of time (ii) protecting against mechanical shock, (iii) strong adhesion to the electronic device and substrates, (iv) easy processing, including sealing, (v) good transparency, particularly in applications in which light or other electromagnetic radiation is important, e.g., solar cell modules, (vi) short cure times with protection of the electronic device from mechanical stress resulting from polymer shrinkage during cure, (vii) high electrical resistance with little, if any, electrical conductance, and (viii) low cost. No one polymeric material delivers maximum performance on all of these properties in any particular application, and usually trade-offs are made to maximize the performance of properties most important to a particular application, e.g., transparency and protection against the environment, at the expense of properties secondary in importance to the application, e.g., cure time and cost. Combinations of polymeric materials are also employed, either as a blend or as separate components of the module.

EVA copolymers with a high content (28 to 35 wt %) of units derived from the vinyl acetate monomer are commonly used to make encapsulant film for use in photovoltaic (PV) modules. See, for example, WO 95/22844, 99/04971, 99/05206 and 2004/055908. EVA resins are typically stabilized with ultra-violet (UV) light additives, and they are typically crosslinked during the solar cell lamination process using peroxides to improve heat and creep resistance to a temperature between about 80 and 90° C. However, EVA resins are less than ideal PV cell encapsulating film material for several reasons. For example, EVA film progressively darkens in intense sunlight due to the EVA resin chemically degrading under the influence of UV light. This discoloration can result in a greater than 30% loss in power output of the solar module after as little as four years of exposure to the environment. EVA resins also absorb moisture and are subject to decomposition.

Moreover and as noted above, EVA resins are typically stabilized with UV additives and crosslinked during the solar cell lamination and/or encapsulation process using peroxides to improve heat resistance and creep at high temperature, e.g., 80 to 90° C. However, because of the C=0 bonds in the EVA molecular structure that absorbs UV radiation and the presence of residual peroxide crosslinking agent in the system after curing, an additive package is used to stabilize the EVA against UV-induced degradation. The residual peroxide is believed to be the primary oxidizing reagent responsible for the generation of chromophores (e.g., U.S. Pat. No. 6,093,757). Additives such as antioxidants, UV-stabilizers, UV-absorbers and others are can stabilize the EVA, but at the same time the additive package can also block UV-wavelengths below 360 nanometers (nm).

Photovoltaic module efficiency depends on photovoltaic cell efficiency and the sun light wavelength passing through the encapsulant. One of the most fundamental limitations on the efficiency of a solar cell is the band gap of its semi-conducting material, i.e., the energy required to boost an electron from the bound valence band into the mobile conduction band. Photons with less energy than the band gap pass through the module without being absorbed. Photons with energy higher than the band gap are absorbed, but their excess energy is wasted (dissipated as heat). In order to increase the photovoltaic cell efficiency, “tandem” cells or multi-junction cells are used to broaden the wavelength range for energy conversion. In addition, in many of the thin film technologies such as amorphous silicon, cadmium telluride, or copper indium gallium selenide, the band gap of the semi-conductive materials is different than that of mono-crystalline silicon. These photovoltaic cells will convert light into electricity for wavelength below 360 nm. For these photovoltaic cells, an encapsulant that can absorb wavelengths below 360 nm is needed to maintain the PV module efficiency.

U.S. Pat. Nos. 6,320,116 and 6,586,271 teach another important property of these polymeric materials, particularly those materials used in the construction of solar cell modules. This property is thermal creep resistance, i.e., resistance to the permanent deformation of a polymer over a period of time as a result of temperature. Thermal creep resistance, generally, is directly proportional to the melting temperature of a polymer. Solar cell modules designed for use in architectural application often need to show excellent resistance to thermal creep at temperatures of 90° C. or higher. For materials with low melting temperatures, e.g., EVA, crosslinking the polymeric material is often necessary to give it higher thermal creep resistance.

Crosslinking, particularly chemical crosslinking, while addressing one problem, e.g., thermal creep, can create other problems. For example, EVA, a common polymeric material used in the construction of solar cell modules and which has a rather low melting point, is often crosslinked using an organic peroxide initiator. While this addresses the thermal creep problem, it creates a corrosion problem, i.e., total crosslinking is seldom, if ever, fully achieved and this leaves residual peroxide in the EVA. This remaining peroxide can promote oxidation and degradation of the EVA polymer and/or electronic device, e.g., through the release of acetic acid over the life of the electronic device module. Moreover, the addition of organic peroxide to EVA requires careful temperature control to avoid premature crosslinking.

Another potential problem with peroxide-initiated cros slinking is the buildup of crosslinked material on the metal surfaces of the process equipment. During extrusion runs, high residence time is experienced at all metal flow surfaces. Over longer periods of extrusion time, crosslinked material can form at the metal surfaces and require cleaning of the equipment. The current practice to minimize gel formation, i.e., this crosslinking of polymer on the metal surfaces of the processing equipment, is to use low processing temperatures which, in turn, reduces the production rate of the extruded product.

One other property that can be important in the selection of a polymeric material for use in the manufacture of an electronic device module is thermoplasticity, i.e., the ability to be softened, molded and formed. For example, if the polymeric material is to be used as a backskin layer in a frameless module, then it should exhibit thermoplasticity during lamination as described in U.S. Pat. No. 5,741,370. This thermoplasticity, however, must not be obtained at the expense of effective thermal creep resistance.

### SUMMARY OF THE INVENTION

In one embodiment, the invention is an electronic device module comprising:
A. at least one electronic device, and
B. a polymeric material in intimate contact with at least one surface of the electronic device, wherein the polymeric material comprises:
   an interpolymer of ethylene and at least one alpha-olefin having, an overall polymer density of not more than 0.905 g/cm³; total unsaturation of not more than 125 per 100,000 carbons; up to 3 long chain branches/1000 carbons; vinyl-3 content of less than 5 per 100,000 carbons; and a total number of vinyl groups/1000 carbons of less than the quantity (8000/Mₙ), wherein the vinyl-3 content and vinyl group measurements are measured by gel permeation chromatography (145° C.) and ¹H-NMR (125° C.), and a grafted silane.

Vinyl trimethoxy silane, vinyl triethoxy silane, (-(meth)acryloxy propyl trimethoxy silane and mixtures of these silanes are preferred silanes for providing the grafted silane for use in this invention.

The polymeric material preferably comprises a ratio of vinyl groups to total olefin groups according to the formula:

VG/TOG>(comonomer mole percentage/0.1)^{a}×10^{a}×0.8

where a=−0.24, VG=vinyl groups, and TOG=total olefin groups.

The polymeric material can also preferably comprise total unsaturation of from about 10 to about 125 per 100,000 carbons total unsaturation; and up to 3 long chain branches/1000 carbons; and a GI200 gel rating of not more than 15.

The polymeric material can also comprise a vinyls amount and a total unsaturation amount, wherein the ratio of vinyls amount:total unsaturation amount is at least 0.2:1, preferably at least 0.3:1, more preferably at least from about 0.4:1 to about 0.8:1; and the polymeric material can have less than 5 per 100,000 carbons of vinyl-3 content. The polymeric material can also have less than 5 per 100,000 carbons of vinyl-3 content.

Another embodiment of the invention are compositions comprising, or made from, at least one ethylenic polymer disclosed herein, wherein at least a portion of the ethylenic polymer has been cross-linked, or functionalized.

Another embodiment includes a photovoltaic film comprising an ethylenic polymer comprising: an overall polymer density of not more than 0.9 g/cm³; total unsaturation of not more than 125 per 100,000 carbons; a GI200 gel rating of not more than 15; vinyl-3 content of less than 5 per 100,000 carbons; and a vinyls amount and a total unsaturation amount, wherein the ratio of vinyls amount:total unsaturation amount is between 0.4:1 and 0.8:1.

“In intimate contact” and like terms mean that the polymeric material is in contact with at least one surface of the device or other article in a similar manner as a coating is in contact with a substrate, e.g., little, if any gaps or spaces between the polymeric material and the face of the device and with the material exhibiting good to excellent adhesion to the face of the device. After extrusion or other method of applying the polymeric material to at least one surface of the electronic device, the material typically forms and/or cures to a film that can be either transparent or opaque and either flexible or rigid. If the electronic device is a solar cell or other device that requires unobstructed or minimally obstructed access to sunlight or to allow a user to read information from it, e.g., a plasma display unit, then that part of the material that covers the active or “business” surface of the device is highly transparent.

The module can further comprise one or more other components, such as one or more glass cover sheets, and in these embodiments, the polymeric material usually is located between the electronic device and the glass cover sheet in a sandwich configuration. If the polymeric material is applied as a film to the surface of the glass cover sheet opposite the electronic device, then the surface of the film that is in contact with that surface of the glass cover sheet can be smooth or uneven, e.g., embossed or textured.

Typically, polymeric material is a ethylene-based polymer. The polymeric material can fully encapsulate the electronic device, or it can be in intimate contact with only a portion of it, e.g., laminated to one face surface of the device. Optionally, the polymeric material can further comprise a scorch inhibitor, and depending upon the application for which the module is intended, the chemical composition of the copolymer and other factors, the copolymer can remain uncrosslinked or be crosslinked. If crosslinked, then it is crosslinked such that it contains less than about 85 percent xylene soluble extractables as measured by ASTM 2765-95.

In another embodiment, the invention is the electronic device module as described in the two embodiments above except that the polymeric material in intimate contact with at least one surface of the electronic device is a co-extruded material in which at least one outer skin layer (i) does not contain peroxide for crosslinking, and (ii) is the surface which comes into intimate contact with the module. Typically, this outer skin layer exhibits good adhesion to glass. This outer skin of the co-extruded material can comprise any one of a number of different polymers, but is typically the same polymer as the polymer of the peroxide-containing layer but without the peroxide. This embodiment of the invention allows for the use of higher processing temperatures which, in turn, allows for faster production rates without unwanted gel formation in the encapsulating polymer due to extended contact with the metal surfaces of the processing equipment. In another embodiment, the extruded product comprises at least three layers in which the skin layer in contact with the electronic module is without peroxide, and the peroxide-containing layer is a core layer.

In another embodiment, the invention is a method of manufacturing an electronic device module, the method comprising the steps of:
A. Providing at least one electronic device, and
B. Contacting at least one surface of the electronic device with a polymeric material comprising an ethylene interpolymer comprising an overall polymer density of not more than 0.905 g/cm³; total unsaturation of not more than 125 per 100,000 carbons; and a GI200 gel rating of not more than 15; up to 3 long chain branches/1000 carbons; vinyl-3 content of less than 5 per 100,000 carbons; and a total number of vinyl groups/1000 carbons of less than the quantity (8000/Mₙ), wherein the vinyl-3 content and vinyl group measurements are measured by gel permeation chromatography (145° C.) and ¹H-NMR (125° C.), (2) a grafted silane; (3) optionally, free radical initiator, e.g., a peroxide or azo compound, or a photoinitiator, e.g., benzophenone, in an amount of at least about 0.05 wt % based on the weight of the copolymer, and (4) optionally, a co-agent in an amount of at least about 0.05 wt % based upon the weight of the copolymer.

In another embodiment the invention is a method of manufacturing an electronic device, the method comprising the steps of:
A. Providing at least one electronic device, and
B. Contacting at least one surface of the electronic device with polymeric material comprising an ethylene interpolymer comprising an overall polymer density of not more than 0.905 g/cm³; total unsaturation of not more than 125 per 100,000 carbons; and a GI200 gel rating of not more than 15; up to 3 long chain branches/1000 carbons; vinyl-3 content of less than 5 per 100,000 carbons; and a total number of vinyl groups/1000 carbons of less than the quantity (8000/Mₙ), wherein the vinyl-3 content and vinyl group measurements are measured by gel permeation chromatography (145° C.) and ¹H-NMR (125° C.), grafted silane, e.g., vinyl tri-ethoxy silane or vinyl tri-methoxy silane, in an amount of at least about 0.1 wt % based on the weight of the copolymer, (3) optionally, free radical initiator, e.g., a peroxide or azo compound, or a photoinitiator, e.g., benzophenone, in an amount of at least about 0.05 wt % based on the weight of the copolymer, and (4) optionally, a co-agent in an amount of at least about 0.05 wt % based on the weight of the copolymer.

In a variant on both of these two method embodiments, the module further comprises at least one translucent cover layer disposed apart from one face surface of the device, and the polymeric material is interposed in a sealing relationship between the electronic device and the cover layer. “In a sealing relationship” and like terms mean that the polymeric material adheres well to both the cover layer and the electronic device, typically to at least one face surface of each, and that it binds the two together with little, if any, gaps or spaces between the two module components (other than any gaps or spaces that may exist between the polymeric material and the cover layer as a result of the polymeric material applied to the cover layer in the form of an embossed or textured film, or the cover layer itself is embossed or textured).

Moreover, in both of these method embodiments, the polymeric material can further comprise a scorch inhibitor, and the method can optionally include a step in which the copolymer is crosslinked, e.g., either contacting the electronic device and/or glass cover sheet with the polymeric material under crosslinking conditions, or exposing the module to crosslinking conditions after the module is formed such that the polyolefin copolymer contains less than about 85 percent xylene soluble extractables as measured by ASTM 2765-95. Crosslinking conditions include heat (e.g., a temperature of at least about 160° C.), radiation (e.g., at least about 15 mega-rad if by E-beam, or 0.05 joules/cm² if by UV light), moisture (e.g., a relative humidity of at least about 50%), etc.

In another variant on these method embodiments, the electronic device is encapsulated, i.e., fully engulfed or enclosed, within the polymeric material. In another variant on these embodiments, the glass cover sheet is treated with a silane coupling agent, e.g., (-amino propyl tri-ethoxy silane). In another embodiment, the invention is an ethylene/non-polar α-olefin polymeric film characterized in that the film has (i) greater than or equal to (≧) 92% transmittance over the wavelength range from 400 to 1100 nanometers (nm), and (ii) a water vapor transmission rate (WVTR) of less than (<) about 50, preferably <about 15, grams per square meter per day (g/m²-day) at 38° C. and 100% relative humidity (RH).

### BRIEF DESCRIPTION OF THE DRAWINGS

FIG. 1 is a schematic of one embodiment of an electronic device module of this invention, i.e., a rigid photovoltaic (PV) module.

FIG. 2 is a schematic of another embodiment of an electronic device module of this invention, i.e., a flexible PV module.

### DESCRIPTION OF THE PREFERRED EMBODIMENTS

The polyolefin copolymers useful in the practice of this invention, also referred to as ethylene interpolyers and as will be described further in more specific detail below, generally have a density of greater than or less than or equal to about 0.90, preferably less than about 0.89, more preferably less than about 0.885, even more preferably less than about 0.88 and even more preferably less than about 0.875, g/cc. The polyolefin copolymers typically have a density greater than about 0.85, and more preferably greater than about 0.86, g/cc. Low density polyolefin copolymers are generally characterized as amorphous, flexible and having good optical properties, e.g., high transmission of visible and UV-light and low haze.

The polyolefin copolymers useful in the practice of this invention have a 2% secant modulus of less than about 150, preferably less than about 140, more preferably less than about 120 and even more preferably less than about 100, mPa as measured by the procedure of ASTM D-882-02. The polyolefin copolymers typically have a 2% secant modulus of greater than zero, but the lower the modulus, the better the copolymer is adapted for use in this invention. The secant modulus is the slope of a line from the origin of a stress-strain diagram and intersecting the curve at a point of interest, and it is used to describe the stiffness of a material in the inelastic region of the diagram. Low modulus polyolefin copolymers are particularly well adapted for use in this invention because they provide stability under stress, e.g., less prone to crack upon stress or shrinkage.

The polyolefin copolymers useful in the practice of this invention and that are made with a single site catalyst such as a metallocene catalyst or constrained geometry catalyst, typically have a melting point of less than about 95, preferably less than about 90, more preferably less than about 85, even more preferably less than about 80 and still more preferably less than about 75° C. For polyolefin copolymers made with multi-site catalysts, e.g., Ziegler-Natta and Phillips catalysts, the melting point is typically less than about 125, preferably less than about 120, more preferably less than about 115 and even more preferably less than about 110° C. The melting point is measured by differential scanning calorimetry (DSC) as described, for example, in U.S. Pat. No. 5,783,638. Polyolefin copolymers with a low melting point often exhibit desirable flexibility and thermoplasticity properties useful in the fabrication of the modules of this invention.

The polyolefin copolymers useful in the practice of this invention include ethylene/α-olefin interpolymers having a α-olefin content of between about 15, preferably at least about 20 and even more preferably at least about 25, wt % based on the weight of the interpolymer. These interpolymers typically have an α-olefin content of less than about 50, preferably less than about 45, more preferably less than about 40 and even more preferably less than about 35, wt % based on the weight of the interpolymer. The α-olefin content is measured by ¹³C nuclear magnetic resonance (NMR) spectroscopy using the procedure described in Randall (Rev. Macromol. Chem. Phys., C29 (2&3)). Generally, the greater the α-olefin content of the interpolymer, the lower the density and the more amorphous the interpolymer, and this translates into desirable physical and chemical properties for the protective polymer component of the module.

The α-olefin is preferably a C₃₋₂₀ linear, branched or cyclic α-olefin. The term interpolymer refers to a polymer made from at least two monomers. It includes, for example, copolymers, terpolymers and tetrapolymers. Examples of C₃₋₂₀ α-olefins include propene, 1-butene, 4-methyl-1-pentene, 1-hexene, 1-octene, 1-decene, 1-dodecene, 1-tetradecene, 1-hexadecene, and 1-octadecene. The α-olefins can also contain a cyclic structure such as cyclohexane or cyclopentane, resulting in an α-olefin such as 3-cyclohexyl-1-propene (allyl cyclohexane) and vinyl cyclohexane. Although not α-olefins in the classical sense of the term, for purposes of this invention certain cyclic olefins, such as norbornene and related olefins, are α-olefins and can be used in place of some or all of the α-olefins described above. Similarly, styrene and its related olefins (for example, α-methylstyrene, etc.) are α-olefins for purposes of this invention. Acrylic and methacrylic acid and their respective ionomers, and acrylates and methacrylates, however, are not α-olefins for purposes of this invention. Illustrative polyolefin copolymers include ethylene/propylene, ethylene/butene, ethylene/1-hexene, ethylene/1-octene, ethylene/styrene, and the like. Ethylene/acrylic acid (EAA), ethylene/methacrylic acid (EMA), ethylene/acrylate or methacrylate, ethylene/vinyl acetate and the like are not polyolefin copolymers of this invention. Illustrative terpolymers include ethylene/propylene/1-octene, ethylene/propylene/butene, ethylene/butene/1-octene, and ethylene/butene/styrene. The copolymers can be random or blocky.

More specific examples of the types of olefinic interpolymers useful in this invention include very low density polyethylene (VLDPE) (e.g., FLEXOMER® ethylene/1-hexene polyethylene made by The Dow Chemical Company), homogeneously branched, linear ethylene/α-olefin copolymers (e.g. TAFMER® by Mitsui Petrochemicals Company Limited and EXACT® by Exxon Chemical Company), and homogeneously branched, substantially linear ethylene/α-olefin polymers (e.g., AFFINITY® and ENGAGE® polyethylene available from The Dow Chemical Company) as will be described in more detail below. The more preferred polyolefin copolymers are the homogeneously branched linear and substantially linear ethylene copolymers. The substantially linear ethylene copolymers are especially preferred, and are more fully described in U.S. Pat. Nos. 5,272,236, 5,278,272 and 5,986,028.

Blends of any of the above olefinic interpolymers can also be used in this invention, and the polyolefin copolymers can be blended or diluted with one or more other polymers to the extent that the polymers are (i) miscible with one another, (ii) the other polymers have little, if any, impact on the desirable properties of the polyolefin copolymer, e.g., optics and low modulus, and (iii) the polyolefin copolymers of this invention constitute at least about 70, preferably at least about 75 and more preferably at least about 80, weight percent of the blend. The polyolefin copolymers useful in the practice of this invention have a Tg of less than about −35, preferably less than about −40, more preferably less than about −45 and even more preferably less than about −50° C. as measured by differential scanning calorimetry (DSC) using the procedure of ASTM D-3418-03. Moreover, typically the polyolefin copolymers used in the practice of this invention also have a melt index (MI as measured by the procedure of ASTM D-1238 (190C/2.16 kg) of less than about 100, preferably less than about 75, more preferably less than about 50 and even more preferably less than about 35, g/10 minutes. The typical minimum MI is about 1, and more typically it is about 5.

The polyolefin copolymers useful in the practice of this invention have an SCBDI (Short Chain Branch Distribution Index) or CDBI (Composition Distribution Branch Index) is defined as the weight percent of the polymer molecules having comonomer content within 50 percent of the median total molar comonomer content. The CDBI of a polymer is readily calculated from data obtained from techniques known in the art, such as, for example, temperature rising elution fractionation (abbreviated herein as “TREF”) as described, for example, in Wild et al, Journal of Polymer Science, Poly. Phys. Ed., Vol. 20, p. 441 (1982), or as described in U.S. Pat. Nos. 4,798,081 and 5,008,204. The SCBDI or CDBI for the polyolefin copolymers used in the practice of this present invention is typically greater than about 50, preferably greater than about 60, more preferably greater than about 70, even more preferably greater than about 80, and most preferably greater than about 90 percent.

Due to the low density and modulus of the polyolefin copolymers used in the practice of this invention, these copolymers are typically cured or crosslinked at the time of contact or after, usually shortly after, the module has been constructed. Cros slinking is important to the performance of the copolymer in its function to protect the electronic device from the environment. Specifically, crosslinking enhances the thermal creep resistance of the copolymer and durability of the module in terms of heat, impact and solvent resistance. Crosslinking can be effected by any one of a number of different methods, e.g., by the use of thermally activated initiators, e.g., peroxides and azo compounds; photoinitiators, e.g., benzophenone; radiation techniques including sunlight, UV light, E-beam and x-ray; vinyl silane, e.g., vinyl tri-ethoxy or vinyl tri-methoxy silane; and moisture cure.

As mentioned above, a grafted silane component is employed in the compositions used according to the present invention and can be provided by any silane that will effectively crosslink the polyolefin copolymer and provide enhanced adhesion. In a preferred embodiment of the claimed invention a grafted vinyl silane graft is made as described below by subjecting the polyolefin copolymer or ethylene copolymer to grafting processes or techniques as described below in which at least a part the copolymer is provided with the grafted vinyl silane. As known to practitioners in this area, the vinyl or unsaturated silanes employed in this fashion, after grafting and becoming grafted to a polymer, including the polyolefin copolymer, are no longer technically “vinyl” silanes in that they are no longer unsaturated but are still sometimes referred to grafted vinyl silanes based on being derived from and remnants of vinyl silanes. In another embodiment a separate, compatible vinyl silane grafted polymer is made and added to polyolefin copolymer of the polymeric material.

Suitable silanes include unsaturated silanes that comprise an ethylenically unsaturated hydrocarbyl group, such as a vinyl, allyl, isopropenyl, butenyl, cyclohexenyl or (-(meth)acryloxy allyl group, and a hydrolyzable group, such as, for example, a hydrocarbyloxy, hydrocarbonyloxy, or hydrocarbylamino group. Examples of hydrolyzable groups include methoxy, ethoxy, formyloxy, acetoxy, proprionyloxy, and alkyl or arylamino groups. Preferred silanes are the unsaturated alkoxy silanes which can be grafted onto the polymer. These silanes and their method of preparation are more fully described in U.S. Pat. No. 5,266,627. Vinyl trimethoxy silane, vinyl triethoxy silane, (-(meth)acryloxy propyl trimethoxy silane and mixtures of these silanes are the preferred silane crosslinkers for is use in this invention. If filler is present, then preferably the crosslinker includes vinyl triethoxy silane.

The amount of silane crosslinker used in the practice of this invention can vary widely depending upon the nature of the polyolefin copolymer, the silane, the processing conditions, the grafting efficiency, the ultimate application, and similar factors, but typically at least 0.5, preferably at least 0.7, parts per hundred resin wt % is used based on the weight of the copolymer. Considerations of convenience and economy are usually the two principal limitations on the maximum amount of silane crosslinker used in the practice of this invention, and typically the maximum amount of silane crosslinker does not exceed 5, preferably it does not exceed 2, wt % based on the weight of the copolymer.

The silane crosslinker is grafted to the polyolefin copolymer by any conventional method, typically in the presence of a free radical initiator e.g. peroxides and azo compounds, or by ionizing radiation, etc. These are discussed in more detail below. Organic initiators are preferred, such as any of those described above, e.g., the peroxide and azo initiators. The amount of initiator can vary, but it is typically present in the amounts described above for the crosslinking of the polyolefin copolymer.

While any conventional method can be used to graft the silane crosslinker to the polyolefin copolymer, one preferred method is blending the two with the initiator in the first stage of a reactor extruder, such as a Buss kneader. The grafting conditions can vary, but the melt temperatures are typically between 160 and 260° C., preferably between 190 and 230° C., depending upon the residence time and the half life of the initiator.

The free radical initiators used in the practice of this invention to graft silane and/or crosslink the polyolefin copolymers include any thermally activated compound that is relatively unstable and easily breaks into at least two radicals. Representative of this class of compounds are the peroxides, particularly the organic peroxides, and the azo initiators. Of the free radical initiators used as crosslinking agents, the dialkyl peroxides and diperoxyketal initiators are preferred. These compounds are described in the Encyclopedia of Chemical Technology, 3rd edition, Vol. 17, pp 27-90. (1982).

In the group of dialkyl peroxides, the preferred initiators are: dicumyl peroxide, di-t-butyl peroxide, t-butyl cumyl peroxide, 2,5-dimethyl-2,5-di(t-butylperoxy)-hexane, 2,5-dimethyl-2,5-di(t-amylperoxy)-hexane, 2,5-dimethyl-2,5-di(t-butylperoxy)hexyne-3, 2,5-dimethyl-2,5-di(t-amylperoxy)hexyne-3, α,α-di[t-butylperoxy)-isopropyl]-benzene, di-t-amyl peroxide, 1,3,5-tri-[t-butylperoxy)-isopropyl]benzene, 1,3-dimethyl-3-(t-butylperoxy)butanol, 1,3-dimethyl-3-(t-amylperoxy)butanol and mixtures of two or more of these initiators.

In the group of diperoxyketal initiators, the preferred initiators are: 1,1-di(t-butylperoxy)-3,3,5-trimethylcyclohexane, 1,1-di(t-butylperoxy)cyclohexane n-butyl, 4,4-di(t-amylperoxy)valerate, ethyl 3,3-di(t-butylperoxy)butyrate, 2,2-di(t-amylperoxy)propane, 3,6,6,9,9-pentamethyl-3-ethoxycarbonylmethyl-1,2,4,5-tetraoxacyclononane, n-butyl-4,4-bis(t-butylperoxy)-valerate, ethyl-3,3-di(t-amylperoxy)-butyrate and mixtures of two or more of these initiators.

Other peroxide initiators, e.g., 00-t-butyl-O-hydrogen-monoperoxysuccinate; 004-amyl-O-hydrogen-monoperoxysuccinate and/or azo initiators e.g., 2,2′-azobis-(2-acetoxypropane), may also be used to provide a crosslinked polymer matrix. Other suitable azo compounds include those described in U.S. Pat. Nos. 3,862,107 and 4,129,531. Mixtures of two or more free radical initiators may also be used together as the initiator within the scope of this invention. In addition, free radicals can form from shear energy, heat or radiation.

The amount of peroxide or azo initiator present in the crosslinkable compositions of this invention can vary widely, but the minimum amount is that sufficient to afford the desired range of crosslinking. The minimum amount of initiator is typically at least about 0.05, preferably at least about 0.1 and more preferably at least about 0.25, wt % based upon the weight of the polymer or polymers to be crosslinked. The maximum amount of initiator used in these compositions can vary widely, and it is typically determined by such factors as cost, efficiency and degree of desired crosslinking desired. The maximum amount is typically less than about 10, preferably less than about 5 and more preferably less than about 3, wt % based upon the weight of the polymer or polymers to be crosslinked.

Free radical crosslinking initiation via electromagnetic radiation, e.g., sunlight, ultraviolet (UV) light, infrared (IR) radiation, electron beam, beta-ray, gamma-ray, x-ray and neutron rays, may also be employed. Radiation is believed to affect crosslinking by generating polymer radicals, which may combine and crosslink. The Handbook of Polymer Foams and Technology, supra, at pp. 198-204, provides additional teachings. Elemental sulfur may be used as a crosslinking agent for diene containing polymers such as EPDM and polybutadiene. The amount of radiation used to cure the copolymer will vary with the chemical composition of the copolymer, the composition and amount of initiator, if any, the nature of the radiation, and the like, but a typical amount of UV light is at least about 0.05, more typically at about 0.1 and even more typically at least about 0.5, Joules/cm², and a typical amount of E-beam radiation is at least about 0.5, more typically at least about 1 and even more typically at least about 1.5, megarads.

If sunlight or UV light is used to effect cure or crosslinking, then typically and preferably one or more photoinitiators are employed. Such photoinitiators include organic carbonyl compounds such as such as benzophenone, benzanthrone, benzoin and alkyl ethers thereof, 2,2-diethoxyacetophenone, 2,2-dimethoxy, 2 phenylacetophenone, p-phenoxy dichloroacetophenone, 2-hydroxycyclohexylphenone, 2-hydroxyisopropylphenone, and 1-phenylpropanedione-2-(ethoxy carboxyl)oxime. These initiators are used in known manners and in known quantities, e.g., typically at least about 0.05, more typically at least about 0.1 and even more typically about 0.5, wt % based on the weight of the copolymer.

If moisture, i.e., water, is used to effect cure or crosslinking, then typically and preferably one or more hydrolysis/condensation catalysts are employed. Such catalysts include Lewis acids such as dibutyltin dilaurate, dioctyltin dilaurate, stannous octonoate, and hydrogen sulfonates such as sulfonic acid.

Free radical crosslinking coagents, i.e. promoters or co-initiators, include multifunctional vinyl monomers and polymers, triallyl cyanurate and trimethylolpropane trimethacrylate, divinyl benzene, acrylates and methacrylates of polyols, allyl alcohol derivatives, and low molecular weight polybutadiene. Sulfur crosslinking promoters include benzothiazyl disulfide, 2-mercaptobenzothiazole, copper dimethyldithiocarbamate, dipentamethylene thiuram tetrasulfide, tetrabutylthiuram disulfide, tetramethylthiuram disulfide and tetramethylthiuram monosulfide.

These coagents are used in known amounts and known ways. The minimum amount of coagent is typically at least about 0.05, preferably at least about 0.1 and more preferably at least about 0.5, wt % based upon the weight of the polymer or polymers to be crosslinked. The maximum amount of coagent used in these compositions can vary widely, and it is typically determined by such factors as cost, efficiency and degree of desired crosslinking desired. The maximum amount is typically less than about 10, preferably less than about 5 and more preferably less than about 3, wt % based upon the weight of the polymer or polymers to be crosslinked.

One difficulty in using thermally activated free radical initiators to promote crosslinking, i.e., curing, of thermoplastic materials is that they may initiate premature crosslinking, i.e., scorch, during compounding and/or processing prior to the actual phase in the overall process in which curing is desired. With conventional methods of compounding, such as milling, Banbury, or extrusion, scorch occurs when the time-temperature relationship results in a condition in which the free radical initiator undergoes thermal decomposition which, in turn, initiates a crosslinking reaction that can create gel particles in the mass of the compounded polymer. These gel particles can adversely impact the homogeneity of the final product. Moreover, excessive scorch can so reduce the plastic properties of the material that it cannot be efficiently processed with the likely possibility that the entire batch will be lost.

One method of minimizing scorch is the incorporation of scorch inhibitors into the compositions. For example, British patent 1,535,039 discloses the use of organic hydroperoxides as scorch inhibitors for peroxide-cured ethylene polymer compositions. U.S. Pat. No. 3,751,378 discloses the use of N-nitroso diphenylamine or N,N′-dinitroso-para-phenylamine as scorch retardants incorporated into a polyfunctional acrylate crosslinking monomer for providing long Mooney scorch times in various copolymer formulations. U.S. Pat. No. 3,202,648 discloses the use of nitrites such as isoamyl nitrite, tert-decyl nitrite and others as scorch inhibitors for polyethylene. U.S. Pat. No. 3,954,907 discloses the use of monomeric vinyl compounds as protection against scorch. U.S. Pat. No. 3,335,124 describes the use of aromatic amines, phenolic compounds, mercaptothiazole compounds, bis(N,N-disubstituted-thiocarbamoyl) sulfides, hydroquinones and dialkyldithiocarbamate compounds. U.S. Pat. No. 4,632,950 discloses the use of mixtures of two metal salts of disubstituted dithiocarbamic acid in which one metal salt is based on copper.

One commonly used scorch inhibitor for use in free radical, particularly peroxide, initiator-containing compositions is 4-hydroxy-2,2,6,6-tetramethylpiperidin-1-oxyl also known as nitroxyl 2, or NR 1, or 4-oxypiperidol, or tanol, or tempol, or tmpn, or probably most commonly, 4-hydroxy-TEMPO or even more simply, h-TEMPO. The addition of 4-hydroxy-TEMPO minimizes scorch by “quenching” free radical crosslinking of the crosslinkable polymer at melt processing temperatures.

The preferred amount of scorch inhibitor used in the compositions of this invention will vary with the amount and nature of the other components of the composition, particularly the free radical initiator, but typically the minimum amount of scorch inhibitor used in a system of polyolefin copolymer with 1.7 weight percent (wt %) peroxide is at least about 0.01, preferably at least about 0.05, more preferably at least about 0.1 and most preferably at least about 0.15, wt % based on the weight of the polymer. The maximum amount of scorch inhibitor can vary widely, and it is more a function of cost and efficiency than anything else. The typical maximum amount of scorch inhibitor used in a system of polyolefin copolymer with 1.7 wt % peroxide does not exceed about 2, preferably does not exceed about 1.5 and more preferably does not exceed about 1, wt % based on the weight of the copolymer.

The polymeric materials of this invention can comprise other additives as well. For example, such other additives include UV-stabilizers and processing stabilizers such as trivalent phosphorus compounds. The UV-stabilizers are useful in lowering the wavelength of electromagnetic radiation that can be absorbed by a PV module (e.g., to less than 360 nm), and include hindered phenols such as Cyasorb UV2908 and hindered amines such as Cyasorb UV 3529, Hostavin N30, Univil 4050, Univin 5050, Chimassorb UV 119, Chimassorb 944 LD, Tinuvin 622 LD and the like. The phosphorus compounds include phosphonites (PEPQ) and phosphites (Weston 399, TNPP, P-168 and Doverphos 9228). The UV-stabilizers include UV absorbers that can also be incorporated into the films to provide additional protection. Examples of absorbers can include but are not limited to Benzophenone-type absorbers such as Cyasorb UV-531, Benzotriazole-type absorbers such as Cyasorb UV-5411, Triazine-type absorbers such as Cyasorb UV-1164, and oxanalide-type absorbers such as Tinuvin 312. The amount of UV-stabilizer is typically from about 0.1 to 0.8%, and preferably from about 0.2 to 0.5%. The amount of processing stabilizer is typically from about 0.02 to 0.5%, and preferably from about 0.05 to 0.15%.

Still other additives include, but are not limited to, antioxidants (e.g., hindered phenolics) (e.g., Irganox® 1010 made by Ciba Geigy Corp.), cling additives, e.g., PIB, anti-blocks, anti-slips, pigments, anti-stats, and fillers (clear if transparency is important to the application). In-process additives, e.g. calcium stearate, water, etc., may also be used. These and other potential additives are used in the manner and amount as is commonly known in the art.

The polymeric materials of this invention are used to construct electronic device modules in the same manner and using the same amounts as the encapsulant materials known in the art, e.g., such as those taught in U.S. Pat. No. 6,586,271, US Patent Application Publication US2001/0045229 A1, WO 99/05206 and WO 99/04971. These materials can be used as “skins” for the electronic device, i.e., applied to one or both face surfaces of the device, or as an encapsulant in which the device is totally enclosed within the material. Typically, the polymeric material is applied to the device by one or more lamination techniques in which a layer of film formed from the polymeric material is applied first to one face surface of the device, and then to the other face surface of the device. In an alternative embodiment, the polymeric material can be extruded in molten form onto the device and allowed to congeal on the device. The polymeric materials of this invention exhibit good adhesion for the face surfaces of the device.

In one embodiment, the electronic device module comprises (i) at least one electronic device, typically a plurality of such devices arrayed in a linear or planar pattern, (ii) at least one glass cover sheet, typically a glass cover sheet over both face surfaces of the device, and (iii) at least one polymeric material. The polymeric material is typically disposed between the glass cover sheet and the device, and the polymeric material exhibits good adhesion to both the device and the sheet. If the device requires access to specific forms of electromagnetic radiation, e.g., sunlight, infrared, ultra-violet, etc., then the polymeric material exhibits good, typically excellent, transparency for that radiation, e.g., transmission rates in excess of 90, preferably in excess of 95 and even more preferably in excess of 97, percent as measured by UV-vis spectroscopy (measuring absorbance in the wavelength range of about 250-1200 nanometers. An alternative measure of transparency is the internal haze method of ASTM D-1003-00. If transparency is not a requirement for operation of the electronic device, then the polymeric material can contain opaque filler and/or pigment.

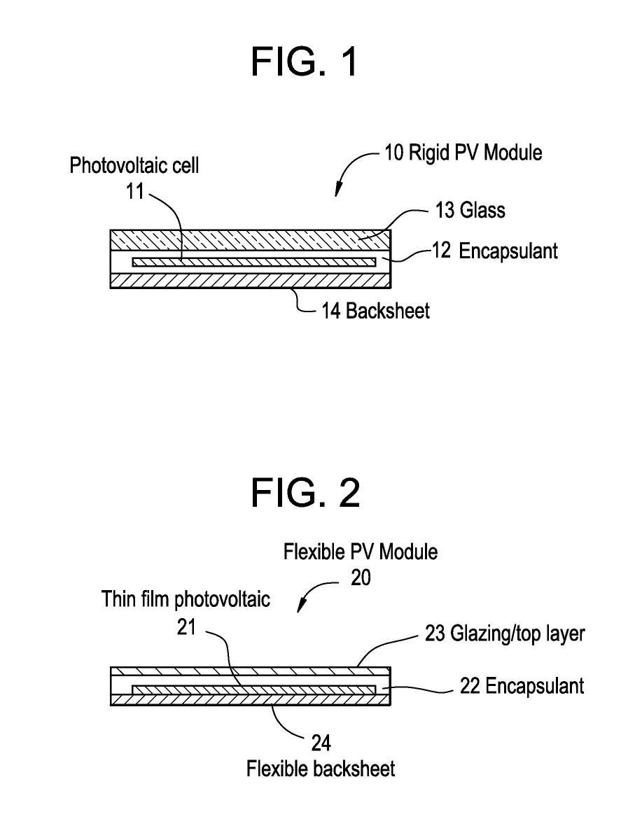

In FIG. 1, rigid PV module 10 comprises photovoltaic cell 11 surrounded or encapsulated by transparent protective layer or encapsulant 12 comprising a polyolefin copolymer used in the practice of this invention. Glass cover sheet 13 covers a front surface of the portion of the transparent protective layer disposed over PV cell 11. Backskin or back sheet 14, e.g., a second glass cover sheet or another substrate of any kind, supports a rear surface of the portion of transparent protective layer 12 disposed on a rear surface of PV cell 11. Backskin layer 14 need not be transparent if the surface of the PV cell to which it is opposed is not reactive to sunlight. In this embodiment, protective layer 12 encapsulates PV cell 11. The thicknesses of these layers, both in an absolute context and relative to one another, are not critical to this invention and as such, can vary widely depending upon the overall design and purpose of the module. Typical thicknesses for protective layer 12 are in the range of about 0.125 to about 2 millimeters (mm), and for the glass cover sheet and backskin layers in the range of about 0.125 to about 1.25 mm. The thickness of the electronic device can also vary widely.

In FIG. 2, flexible PV module 20 comprises thin film photovoltaic 21 over-lain by transparent protective layer or encapsulant 22 comprising a polyolefin copolymer used in the practice of this invention. Glazing/top layer 23 covers a front surface of the portion of the transparent protective layer disposed over thin film PV 21. Flexible backskin or back sheet 24, e.g., a second protective layer or another flexible substrate of any kind, supports the bottom surface of thin film PV 21. Backskin layer 24 need not be transparent if the surface of the thin film cell which it is supporting is not reactive to sunlight. In this embodiment, protective layer 21 does not encapsulate thin film PV 21. The overall thickness of a typical rigid or flexible PV cell module will typically be in the range of about 5 to about 50 mm.

The modules described in FIGS. 1 and 2 can be constructed by any number of different methods, typically a film or sheet co-extrusion method such as blown-film, modified blown-film, calendaring and casting and lamination. In one method and referring to FIG. 1, protective layer 14 is formed by first extruding a polyolefin copolymer over and onto the top surface of the PV cell and either simultaneously with or subsequent to the extrusion of this first extrusion, extruding the same, or different, polyolefin copolymer over and onto the back surface of the cell. Once the protective film is attached the PV cell, the glass cover sheet and backskin layer can be attached in any convenient manner, e.g., extrusion, lamination, etc., to the protective layer, with or without an adhesive. Either or both external surfaces, i.e., the surfaces opposite the surfaces in contact with the PV cell, of the protective layer can be embossed or otherwise treated to enhance adhesion to the glass and backskin layers. The module of FIG. 2 can be constructed in a similar manner, except that the backskin layer is attached to the PV cell directly, with or without an adhesive, either prior or subsequent to the attachment of the protective layer to the PV cell.

### DEFINITIONS

The term “composition,” as used, includes a mixture of materials which comprise the composition, as well as reaction products and decomposition products formed from the materials of the composition.

The terms “blend” or “polymer blend,” as used, mean an intimate physical mixture (that is, without reaction) of two or more polymers. A blend may or may not be miscible (not phase separated at molecular level). A blend may or may not be phase separated. A blend may or may not contain one or more domain configurations, as determined from transmission electron spectroscopy, light scattering, x-ray scattering, and other methods known in the art. The blend may be effected by physically mixing the two or more polymers on the macro level (for example, melt blending resins or compounding) or the micro level (for example, simultaneous forming within the same reactor).

The term “linear” refers to polymers where the polymer backbone of the polymer lacks measurable or demonstrable long chain branches, for example, the polymer is substituted with an average of less than 0.01 long branch per 1000 carbons.

The term “polymer” refers to a polymeric compound prepared by polymerizing monomers, whether of the same or a different type. The generic term polymer thus embraces the term “homopolymer,” usually employed to refer to polymers prepared from only one type of monomer, and the term “interpolymer” as defined. The terms “ethylene/α-olefin polymer” is indicative of interpolymers as described.

The term “interpolymer” refers to polymers prepared by the polymerization of at least two different types of monomers. The generic term interpolymer includes copolymers, usually employed to refer to polymers prepared from two different monomers, and polymers prepared from more than two different types of monomers.

The term “ethylene-based polymer” refers to a polymer that contains more than 50 mole percent polymerized ethylene monomer (based on the total amount of polymerizable monomers) and, optionally, may contain at least one comonomer.

The term “ethylene/α-olefin interpolymer” refers to an interpolymer that contains more than 50 mole percent polymerized ethylene monomer (based on the total amount of polymerizable monomers) and at least one α-olefin.

The term “ethylenic polymer” refers to a polymer resulting from the bonding of an ethylene-based polymer and at least one highly long chain branched ethylene-based polymer.

### Test Methods

Density

Density (g/cm³) is measured according to ASTM-D 792-03, Method B, in isopropanol. Specimens are measured within 1 hour of molding after conditioning in the isopropanol bath at 23° C. for 8 min to achieve thermal equilibrium prior to measurement. The specimens are compression molded according to ASTM D-4703-00 Annex A with a 5 min initial heating period at about 190° C. and a 15° C./min cooling rate per Procedure C. The specimen is cooled to 45° C. in the press with continued cooling until “cool to the touch.”

Melt Index

Melt index, or I₂, is measured in accordance with ASTM D 1238, Condition 190° C./2.16 kg, and is reported in grams eluted per 10 minutes. I₁₀ is measured in accordance with ASTM D 1238, Condition 190° C./10 kg, and is reported in grams eluted per 10 minutes.

DSC Crystallinity

Differential Scanning calorimetry (DSC) can be used to measure the melting and crystallization behavior of a polymer over a wide range of temperature. For example, the TA Instruments Q1000 DSC, equipped with an RCS (refrigerated cooling system) and an autosampler is used to perform this analysis. During testing, a nitrogen purge gas flow of 50 ml/min is used. Each sample is melt pressed into a thin film at about 175° C.; the melted sample is then air-cooled to room temperature (−25° C.). A 3-10 mg, 6 mm diameter specimen is extracted from the cooled polymer, weighed, placed in a light aluminum pan (ca 50 mg), and crimped shut. Analysis is then performed to determine its thermal properties.

The thermal behavior of the sample is determined by ramping the sample temperature up and down to create a heat flow versus temperature profile. First, the sample is rapidly heated to 180° C. and held isothermal for 3 minutes in order to remove its thermal history. Next, the sample is cooled to −40° C. at a 10° C./minute cooling rate and held isothermal at −40° C. for 3 minutes. The sample is then heated to 150° C. (this is the “second heat” ramp) at a 10° C./minute heating rate. The cooling and second heating curves are recorded. The cool curve is analyzed by setting baseline endpoints from the beginning of crystallization to −20° C. The heat curve is analyzed by setting baseline endpoints from −20° C. to the end of melt. The values determined are peak melting temperature (Tₘ), peak crystallization temperature (T_{c}), heat of fusion (H_{f}) (in Joules per gram), and the calculated % crystallinity for polyethylene samples using:

% Crystallinity=((H_{f})/(292 J/g))×100.

The heat of fusion (H_{f}) and the peak melting temperature are reported from the second heat curve. Peak crystallization temperature is determined from the cooling curve.

Gel Permeation Chromatography (GPC)

The GPC system consists of a Waters (Milford, Mass.) 150° C. high temperature chromatograph (other suitable high temperatures GPC instruments include Polymer Laboratories (Shropshire, UK) Model 210 and Model 220) equipped with an on-board differential refractometer (RI). Additional detectors can include an IR4 infra-red detector from Polymer ChAR (Valencia, Spain), Precision Detectors (Amherst, Mass.) 2-angle laser light scattering detector Model 2040, and a Viscotek (Houston, Tex.) 150R 4-capillary solution viscometer. A GPC with the last two independent detectors and at least one of the first detectors is sometimes referred to as “3D-GPC”, while the term “GPC” alone generally refers to conventional GPC. Depending on the sample, either the 15-degree angle or the 90-degree angle of the light scattering detector is used for calculation purposes. Data collection is performed using Viscotek TriSEC software, Version 3, and a 4-channel Viscotek Data Manager DM400. The system is also equipped with an on-line solvent degassing device from Polymer Laboratories (Shropshire, UK). Suitable high temperature GPC columns can be used such as four 30 cm long Shodex HT803 13 micron columns or four 30 cm Polymer Labs columns of 20-micron mixed-pore-size packing (MixA LS, Polymer Labs). The sample carousel compartment is operated at 140° C. and the column compartment is operated at 150° C. The samples are prepared at a concentration of 0.1 grams of polymer in 50 milliliters of solvent. The chromatographic solvent and the sample preparation solvent contain 200 ppm of butylated hydroxytoluene (BHT). Both solvents are sparged with nitrogen. The polyethylene samples are gently stirred at 160° C. for four hours. The injection volume is 200 microliters. The flow rate through the GPC is set at 1 ml/minute.

The GPC column set is calibrated before running the Examples by running twenty-one narrow molecular weight distribution polystyrene standards. The molecular weight (MW) of the standards ranges from 580 to 8,400,000 grams per mole, and the standards are contained in 6 “cocktail” mixtures. Each standard mixture has at least a decade of separation between individual molecular weights. The standard mixtures are purchased from Polymer Laboratories (Shropshire, UK). The polystyrene standards are prepared at 0.025 g in 50 mL of solvent for molecular weights equal to or greater than 1,000,000 grams per mole and 0.05 g in 50 ml of solvent for molecular weights less than 1,000,000 grams per mole. The polystyrene standards were dissolved at 80° C. with gentle agitation for 30 minutes. The narrow standards mixtures are run first and in order of decreasing highest molecular weight component to minimize degradation. The polystyrene standard peak molecular weights are converted to polyethylene M_{w} using the Mark-Houwink K and a (sometimes referred to as a) values mentioned later for polystyrene and polyethylene. See the Examples section for a demonstration of this procedure.

With 3D-GPC absolute weight average molecular weight (“M_{w,Abs}”) and intrinsic viscosity are also obtained independently from suitable narrow polyethylene standards using the same conditions mentioned previously. These narrow linear polyethylene standards may be obtained from Polymer Laboratories (Shropshire, UK; Part No.'s PL2650-0101 and PL2650-0102).

The systematic approach for the determination of multi-detector offsets is performed in a manner consistent with that published by Balke, Mourey, et al. (Mourey and Balke, Chromatography Polym., Chapter 12, (1992)) (Balke, Thitiratsakul, Lew, Cheung, Mourey, Chromatography Polym., Chapter 13, (1992)), optimizing triple detector log (M_{w} and intrinsic viscosity) results from Dow 1683 broad polystyrene (American Polymer Standards Corp.; Mentor, Ohio) or its equivalent to the narrow standard column calibration results from the narrow polystyrene standards calibration curve. The molecular weight data, accounting for detector volume off-set determination, are obtained in a manner consistent with that published by Zimm (Zimm, B. H., J. Chem. Phys., 16, 1099 (1948)) and Kratochvil (Kratochvil, P., Classical Light Scattering from Polymer Solutions, Elsevier, Oxford, N.Y. (1987)). The overall injected concentration used in the determination of the molecular weight is obtained from the mass detector area and the mass detector constant derived from a suitable linear polyethylene homopolymer, or one of the polyethylene standards. The calculated molecular weights are obtained using a light scattering constant derived from one or more of the polyethylene standards mentioned and a refractive index concentration coefficient, dn/dc, of 0.104. Generally, the mass detector response and the light scattering constant should be determined from a linear standard with a molecular weight in excess of about 50,000 daltons. The viscometer calibration can be accomplished using the methods described by the manufacturer or alternatively by using the published values of suitable linear standards such as Standard Reference Materials (SRM) 1475a, 1482a, 1483, or 1484a. The chromatographic concentrations are assumed low enough to eliminate addressing 2^{nd} viral coefficient effects (concentration effects on molecular weight).

Analytical Temperature Rising Elution Fractionation (ATREF)

High Density Fraction (percent) is measured via analytical temperature rising elution fractionation analysis (ATREF). ATREF analysis is conducted according to the method described in U.S. Pat. No. 4,798,081 and Wilde, L.; Ryle, T. R.; Knobeloch, D. C.; Peat, I. R.; Determination of Branching Distributions in Polyethylene and Ethylene Copolymers, Journal of Polymer Science, 20, 441-455 (1982). The composition to be analyzed is dissolved in trichlorobenzene and allowed to crystallize in a column containing an inert support (stainless steel shot) by slowly reducing the temperature to 20° C. at a cooling rate of 0.1° C./min. The column is equipped with an infrared detector. An ATREF chromatogram curve is then generated by eluting the crystallized polymer sample from the column by slowly increasing the temperature of the eluting solvent (trichlorobenzene) from 20 to 120° C. at a rate of 1.5° C./min Viscosity average molecular weight (Mv) of the eluting polymer is measured and reported. An ATREF plot has the short chain branching distribution (SCBD) plot and a molecular weight plot. The SCBD plot has 3 peaks, one for the high crystalline fraction (typically above 90° C.), one for copolymer fraction (typically in between 30-90° C.) and one for purge fraction (typically below 30° C.). The curve also has a valley in between the copolymer and the high crystalline fraction. Thc is the lowest temperature in this valley. % High density (HD) fraction is the area under the curve above Thc. Mv is the viscosity average molecular weight from ATREF. Mhc is the average Mv for fraction above Thc. Mc is the average Mv of copolymer between 60-90° C. Mp is the average Mv of whole polymer.

Fast Temperature Rising Elution Fractionation (F-TREF)

The fast-TREF can be performed with a Crystex instrument by Polymer ChAR (Valencia, Spain) in orthodichlorobenzene (ODCB) with IR-4 infrared detector in compositional mode (Polymer ChAR, Spain) and light scattering (LS) detector (Precision Detector Inc., Amherst, Mass.).

When testing F-TREF, 120 mg of the sample is added into a Crystex reactor vessel with 40 ml of ODCB held at 160° C. for 60 minutes with mechanical stirring to achieve sample dissolution. The sample is loaded onto TREF column. The sample solution is then cooled down in two stages: (1) from 160° C. to 100° C. at 40° C./minute, and (2) the polymer crystallization process started from 100° C. to 30° C. at 0.4° C./minute. Next, the sample solution is held isothermally at 30° C. for 30 minutes. The temperature-rising elution process starts from 30° C. to 160° C. at 1.5° C./minute with flow rate of 0.6 ml/minute. The sample loading volume is 0.8 ml. Sample molecular weight (M_{w}) is calculated as the ratio of the 15° or 90° LS signal over the signal from measuring sensor of IR-4 detector. The LS-MW calibration constant is obtained by using polyethylene national bureau of standards SRM 1484a. The elution temperature is reported as the actual oven temperature. The tubing delay volume between the TREF and detector is accounted for in the reported TREF elution temperature.

Preparative Temperature Rising Elution Fractionation (P-TREF)

The temperature rising elution fractionation method (TREF) can be used to preparatively fractionate the polymers (P-TREF) and is derived from Wilde, L.; Ryle, T. R.; Knobeloch, D. C.; Peat, I. R.; “Determination of Branching Distributions in Polyethylene and Ethylene Copolymers”, J. Polym. Sci., 20, 441-455 (1982), including column dimensions, solvent, flow and temperature program. An infrared (IR) absorbance detector is used to monitor the elution of the polymer from the column. Separate temperature programmed liquid baths—one for column loading and one for column elution—are also used.

Samples are prepared by dissolution in trichlorobenzene (TCB) containing approximately 0.5% 2,6-di-tert-butyl-4-methylphenol at 160° C. with a magnetic stir bar providing agitation. Sample load is approximately 150 mg per column. After loading at 125° C., the column and sample are cooled to 25° C. over approximately 72 hours. The cooled sample and column are then transferred to the second temperature programmable bath and equilibrated at 25° C. with a 4 ml/minute constant flow of TCB. A linear temperature program is initiated to raise the temperature approximately 0.33° C./minute, achieving a maximum temperature of 102° C. in approximately 4 hours.

Fractions are collected manually by placing a collection bottle at the outlet of the IR detector. Based upon earlier ATREF analysis, the first fraction is collected from 56 to 60° C. Subsequent small fractions, called subfractions, are collected every 4° C. up to 92° C., and then every 2° C. up to 102° C. Subfractions are referred to by the midpoint elution temperature at which the subfraction is collected.

Subfractions are often aggregated into larger fractions by ranges of midpoint temperature to perform testing. Fractions may be further combined into larger fractions for testing purposes.

A weight-average elution temperature is determined for each Fraction based upon the average of the elution temperature range for each subfraction and the weight of the subfraction versus the total weight of the sample. Weight average temperature is defined as:

$${T}_{w} = {\sum }_{T}^{ } T ( f ) * A ( f ) / {\sum }_{T}^{ } A ( f ) ,$$

where T(f) is the mid-point temperature of a narrow slice or segment and A(f) is the area of the segment, proportional to the amount of polymer, in the segment.

Data are stored digitally and processed using an EXCEL (Microsoft Corp.; Redmond, Wash.) spreadsheet. The TREF plot, peak maximum temperatures, fraction weight percentages, and fraction weight average temperatures were calculated with the spreadsheet program.

Haze is determined according to ASTM-D 1003.

Gloss 45° is determined according to ASTM-2457.

Elmendorf Tear Resistance is measured according to ASTM-D 1922.

Dart Impact Strength is measured according to ASTM-D 1709-04, Method A.

C13 NMR Comonomer Content

It is well known to use NMR spectroscopic methods for determining polymer composition. ASTM D 5017-96, J. C. Randall et al., in “NMR and Macromolecules” ACS Symposium series 247, J. C. Randall, Ed., Am. Chem. Soc., Washington, D.C., 1984, Ch. 9, and J. C. Randall in “Polymer Sequence Determination”, Academic Press, New York (1977) provide general methods of polymer analysis by NMR spectroscopy.

Residual Unsaturations determined by ¹H Nuclear Magnetic Resonance (NMR):

Samples for ¹H NMR experiments were prepared by dissolving polymers in a solvent mixture, tetrachloroethane-d₂/perchloroethylene (50/50 v/v), in standard NMR tubes. The tubes were then heated in a heating block set at 115° C. until polymers are completely dissolved. The ¹H NMR spectra were taken on a Varian Inova 600 MHz spectrometer using a broadband inverse probe. For each sample, two experiments were performed. The first is a standard single pulse ¹H NMR experiment to quantify the polymer peak relative to the solvent peak. The second is a presaturated ¹H NMR experiment to suppress the polymer backbone peak (˜1.4 ppm). The end groups were then quantified by referencing to the same solvent peak. The following acquisition parameters were used: 5*T₁ relaxation delay, 90 degree pulse of 8 μs, 2 s acquisition time, 0.5 second presaturation time with satpwr=1, 128-256 scans. The spectra are centered at 4 ppm with a spectral width of 10000 Hz. All measurements were taken without sample spinning at 110±1° C. The ¹H NMR spectra were referenced to 5.99 ppm for the resonance peak of the solvent (residual protonated tetrachloroethane).

| Group | Structure | Notation | (ppm) | J (0.5 Hz) |
|---|---|---|---|---|
| Vinylene | 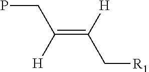 | Vy1-trans | 5.49 | Triplet (3.8) |
| | 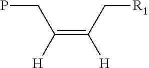 | Vy1-cis | 5.44 | Triplet (4.4) |
| | 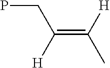 | Vy2-trans | ~5.52 | Multiplet |
| | 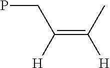 | Vy2-cis | ~5.49 | Multiplet |
| | 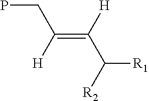 | Vy3 | 5.43 5.26 | Dual-triplet (15.0, 7.0) Dual- doublet (15.3, 7.8) |
| Trisubstituted unsaturation | 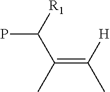 | T1-trans | 5.28 | Quartet (6.4) |
| | 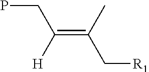 | T2-cis | 5.23 5.22 | Triplet (6.5) Triplet (6.5) |
| | 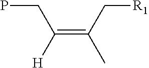 | T2-trans | | |
| | 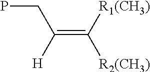 | T3 T4 T5 | 5.23 5.20 5.18 | Triplet (6.2) Triplet (~6) Triplet (?) |
| | 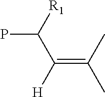 | T6 | 4.95 | |
| Vinyl | 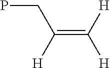 | V1 | 5.90 5.07 5.01 | Dual-dual- triplet Doublet (17.1) Doublet (10.3) |
| | 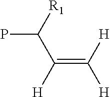 | V2 | 5.67 ~5.03 | |
| Vinylidene | 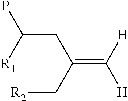 | Vd1 | 4.86 4.81 | Singlet Singlet |
| | 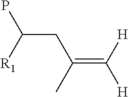 | Vd2 | 4.83 4.76 | Singlet Singlet |
| | 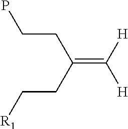 | Vd3 | 4.80 | Singlet |

Gel Rating of the Polymers

### Gels

Method/Description of GI200 Test

Extruder: Model OCS ME 20 available from OCS Optical Control Systems GmbH Wullener Feld 36, 58454 Witten, Germany or equivalent.

| Parameter | Standard Screw |
|---|---|
| L/D | 25/1 |
| Coating | Chrome |
| Compression ratio | 3/1 |
| Feed Zone | 10D |
| Transition Zone | 3D |
| Metering Zone | 12D |
| Mixing Zone | — |

Cast Film Die: ribbon die, 150×0.5 mm, available from OCS Optical Control Systems GmbH, or equivalent.

Air Knife: OCS air knife to pin the film on the chill roll, available from OCS Optical Control Systems GmbH, or equivalent.

Cast Film Chill Rolls and Winding Unit: OCS Model CR-8, available for OCS Optical Control Systems GmbH, or equivalent.

| Profile Number | | 070 | 071 | 072 |
|---|---|---|---|---|
| MELT INDEX | dg/min | 0.1-1.2 | 1.2-3.2 | 3.2-32 |
| Density | g/cm³ | ALL | ALL | ALL |
| Throat | ° C. | 25 ± 3 | 25 ± 3 | 25 ± 3 |
| Zone 1 | ° C. | 180 ± 5 | 160 ± 5 | 140 ± 5 |
| Zone 2 | ° C. | 240 ± 5 | 190 ± 5 | 170 ± 5 |
| Zone 3 | ° C. | 260 ± 5 | 200 ± 5 | 175 ± 5 |
| Zone 4 | ° C. | 260 ± 5 | 210 ± 5 | 175 ± 5 |
| Adapter | ° C. | 260 ± 5 | 225 ± 5 | 180 ± 5 |
| Die | ° C. | 260 ± 5 | 225 ± 5 | 180 ± 5 |
| Screw Type | | Standard | Standard | Standard |
| Screw Speed | RPM | 70 ± 2 | 70 ± 2 | 70 ± 2 |
| Air Knife Flow | Nm³/h | 6 ± 2 | 6 ± 2 | 6 ± 2 |
| Die to Chill Roll | mm | 6 ± 1 | 6 ± 1 | 6 ± 1 |
| Die to Air Knife | mm | 6 ± 1 | 6 ± 1 | 6 ± 1 |
| Chill Speed | m/min | 3 ± 1 | 3 ± 1 | 3 ± 1 |
| Chill Temp. | ° C. | 20 ± 2 | 20 ± 2 | 20 ± 2 |
| Tension Speed | m/min | 6 ± 2 | 6 ± 2 | 6 ± 2 |
| Winder Torque | N | 8 ± 1 | 8 ± 1 | 8 ± 1 |
| Lab Temperature | ° C. | 23 ± 2 | 23 ± 2 | 23 ± 2 |
| Lab Humidity | % | <70 | <70 | <70 |
| Width | mm | 108 ± 18 | 108 ± 18 | 108 ± 18 |
| Thickness | μm | 76 ± 5 | 76 ± 5 | 76 ± 5 |

Gel Counter: OCS FS-3 line gel counter consisting of a lighting unit, a CCD detector and an image processor with the Gel counter software version 3.65e 1991-1999, available from OCS Optical Control Systems GmbH, or equivalent. The OCS FS-5 gel counter is equivalent.

### Instantaneous GI200

Note: GI stands for “gel index”. GI200 includes all gels≧200 μm in diameter.

The instantaneous GI200 is the sum of the area of all the size classes in one analysis cycle:

4

### Xⱼ=ΣA_{T,j,k}

k=1
where:

Xⱼ=instantaneous GI200 (mm²/24.6 cm³) for analysis cycle j

4=total number of size clauses

### GI200

GI200 is defined as the trailing average of the last twenty instantaneous GI200 values:

20

### <X>=ΣXⱼ/20

j=1
where:
<X>=GI200(mm²/24.6 cm³)

One analysis cycle inspects 24.6 cm³ of film. The corresponding area is 0.324 m² for a film thickness of 76 μm and 0.647 m² for a film thickness of 38 μm.

Gel Content Measurement

When the ethylene interpolymer, either alone or contained in a composition is at least partially crosslinked, the degree of crosslinking may be measured by dissolving the composition in a solvent for specified duration, and calculating the percent gel or unextractable component. The percent gel normally increases with increasing crosslinking levels.

Long chain branching per 1000 carbons

The presence of long chain branching can be determined in ethylene homopolymers by using ¹³C nuclear magnetic resonance (NMR) spectroscopy and is quantified using the method described by Randall (Rev. Macromol. Chem. Phys., C29, V. 2&3, 285-297). There are other known techniques useful for determining the presence of long chain branches in ethylene polymers, including ethylene/1-octene interpolymers. Two such exemplary methods are gel permeation chromatography coupled with a low angle laser light scattering detector (GPC-LALLS) and gel permeation chromatography coupled with a differential viscometer detector (GPC-DV). The use of these techniques for long chain branch detection and the underlying theories have been well documented in the literature. See, for example, G. H. and Stockmayer, W. H., J. Chem. Phys., 17, 1301 (1949), and Rudin, A. Modern Methods of Polymer Characterization, John Wiley & Sons, New York (1991) 103-112.

Ethylenic Polymers of this Invention

The ethylenic polymers useful in this invention are relatively high molecular weight, relatively low density polymers that have a unique combination of (A) a relatively low total amount of unsaturation, and (B) a relatively high ratio of vinyl groups to total unsaturated groups in the polymer chain, as compared to known metallocene-catalyzed ethylenic polymers. This combination is believed to result in lower gels for end-use applications (such as films) where low gels are important, better long-term polymer stability and, for end-use applications requiring cross-linking, better control of that cross-linking, in each case while maintaining a good balance of other performance properties.

The novel polymers useful in this invention are interpolymers of ethylene with at least 0.1 mole percent of one or more comonomers, preferably at least one α-olefin comonomer. The α-olefin comonomer(s) may have, for example, from 3 to 20 carbon atoms. Preferably, the α-olefin comonomer may have 3 to 8 carbon atoms. Exemplary α-olefin comonomers include, but are not limited to, propylene, 1-butene, 3-methyl-1-butene, 1-pentene, 3-methyl-1-pentene, 4-methyl-1-pentene, 1-hexene, 1-heptene, 4,4-dimethyl-1-pentene, 3-ethyl-1-pentene, 1-octene, 1-nonene, 1-decene, 1-dodecene, 1-tetradecene, 1-hexadecene, 1-octadecene and 1-eicosene.

Preparation of an Ethylenic Polymer of this Invention

For producing the ethylenic polymers, also referred to herein interchangeably as ethylene interpolymers and/or polyolefin copolymers, for use in polymeric materials of this invention, a solution-phase polymerization process may be used. Typically, such a process occurs in a well-stirred reactor such as a loop reactor or a sphere reactor at temperature from about 150 to about 300° C., preferably from about 160 to about 180° C., and at pressures from about 30 to about 1000 psi, preferably from about 30 to about 750 psi. The residence time in such a process is typically from about 2 to about 20 minutes, preferably from about 10 to about 20 minutes. Ethylene, solvent, catalyst, and one or more comonomers are fed continuously to the reactor. Exemplary solvents include, but are not limited to, isoparaffins. For example, such solvents are commercially available under the name ISOPAR E from ExxonMobil Chemical Co., Houston, Tex. The resultant mixture of ethylene-based polymer and solvent is then removed from the reactor and the polymer is isolated. Solvent is typically recovered via a solvent recovery unit, that is, heat exchangers and vapor liquid separator drum, and is recycled back into the polymerization system.

Suitable catalysts for use in preparing the novel polymers of this invention include any compound or combination of compounds that is adapted for preparing such polymers in the particular type of polymerization process, such as solution-polymerization, slurry-polymerization or gas-phase-polymerization processes.

In one embodiment, an ethylenic polymer of this invention is prepared in a solution-polymerization process using a polymerization catalyst that is a metal complex of a polyvalent aryloxyether corresponding to the formula:

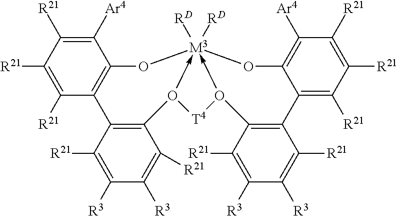

where M³ is Ti, Hf or Zr, preferably Zr;

Ar⁴ independently each occurrence is a substituted C₉₋₂₀ aryl group, wherein the substituents, independently each occurrence, are selected from the group consisting of alkyl; cycloalkyl; and aryl groups; and halo-, trihydrocarbylsilyl- and halohydrocarbyl-substituted derivatives thereof, with the proviso that at least one substituent lacks co-planarity with the aryl group to which it is attached;

T⁴ independently each occurrence is a C₂₋₂₀ alkylene, cycloalkylene or cycloalkenylene group, or an inertly substituted derivative thereof;

R²¹ independently each occurrence is hydrogen, halo, hydrocarbyl, trihydrocarbylsilyl, trihydrocarbylsilylhydrocarbyl, alkoxy or di(hydrocarbyl)amino group of up to 50 atoms not counting hydrogen;

R³ independently each occurrence is hydrogen, halo, hydrocarbyl, trihydrocarbylsilyl, trihydrocarbylsilylhydrocarbyl, alkoxy or amino of up to 50 atoms not counting hydrogen, or two R³ groups on the same arylene ring together or an R³ and an R²¹ group on the same or different arylene ring together form a divalent ligand group attached to the arylene group in two positions or join two different arylene rings together; and

R^{D}, independently each occurrence is halo or a hydrocarbyl or trihydrocarbylsilyl group of up to 20 atoms not counting hydrogen, or 2 R^{D} groups together are a hydrocarbylene, hydrocarbadiyl, diene, or poly(hydrocarbyl)silylene group.

Such polyvalent aryloxyether metal complexes and their synthesis are described in WO 2007/136496 or WO 2007/136497, using the synthesis procedures disclosed in US-A-2004/0010103. Among the preferred polyvalent aryloxyether metal complexes are those disclosed as example 1 in WO 2007/136496 and as example A10 in WO 2007/136497. Suitable cocatalysts and polymerization conditions for use of the preferred polyvalent aryloxyether metal complexes are also disclosed in WO 2007/136496 or WO 2007/136497.

The metal complex polymerization catalyst may be activated to form an active catalyst composition by combination with one or more cocatalysts, preferably a cation forming cocatalyst, a strong Lewis acid, or a combination thereof. Suitable cocatalysts for use include polymeric or oligomeric aluminoxanes, especially methyl aluminoxane, as well as inert, compatible, noncoordinating, ion forming compounds. So-called modified methyl aluminoxane (MMAO) or triethyl aluminum (TEA) is also suitable for use as a cocatalyst. One technique for preparing such modified aluminoxane is disclosed in U.S. Pat. No. 5,041,584 (Crapo et al.). Aluminoxanes can also be made as disclosed in U.S. Pat. Nos. 5,542,199 (Lai et al.); 4,544,762 (Kaminsky et al.); 5,015,749 (Schmidt et al.); and 5,041,585 (Deavenport et al.).

Polymeric Blends or Compounds of this Invention

Various natural or synthetic polymers, and/or other components, may be blended or compounded with the novel polymers of this invention to form the polymeric compositions of this invention. Suitable polymers for blending with the embodiment ethylenic polymer include thermoplastic and non-thermoplastic polymers including natural and synthetic polymers. Suitable synthetic polymers include both ethylene-based polymers, such as high pressure, free-radical low density polyethylene (LDPE), and ethylene-based polymers prepared with Ziegler-Natta catalysts, including high density polyethylene (HDPE) and heterogeneous linear low density polyethylene (LLDPE), ultra low density polyethylene (ULDPE), and very low density polyethylene (VLDPE), as well as multiple-reactor ethylenic polymers (“in reactor” blends of Ziegler-Natta PE and metallocene PE, such as products disclosed in U.S. Pat. Nos. 6,545,088 (Kolthammer et al.); 6,538,070 (Cardwell et al.); 6,566,446 (Parikh et al.); 5,844,045 (Kolthammer et al.); 5,869,575 (Kolthammer et al.); and 6,448,341 (Kolthammer et al.)). Commercial examples of linear ethylene-based polymers include ATTANE™ Ultra Low Density Linear Polyethylene Copolymer, DOWLEX™ Polyethylene Resins, and FLEXOMER™ Very Low Density Polyethylene, all available from The Dow Chemical Company. Other suitable synthetic polymers include polypropylene, (both impact modifying polypropylene, isotactic polypropylene, atactic polypropylene, and random ethylene/propylene copolymers), ethylene/diene interpolymers, ethylene-vinyl acetate (EVA), ethylene/vinyl alcohol copolymers, polystyrene, impact modified polystyrene, ABS, styrene/butadiene block copolymers and hydrogenated derivatives thereof (SBS and SEBS), and thermoplastic polyurethanes. Homogeneous olefin-based polymers such as ethylene-based or propylene-based plastomers or elastomers can also be useful as components in blends or compounds made with the ethylenic polymers of this invention. Commercial examples of homogeneous metallocene-catalyzed, ethylene-based plastomers or elastomers include AFFINITY™ polyolefin plastomers and ENGAGE™ polyolefin elastomers, both available from The Dow Chemical Company, and commercial examples of homogeneous propylene-based plastomers and elastomers include VERSIFY™ performance polymers, available from The Dow Chemical Company, and VISTAMAX™ polymers available from ExxonMobil Chemical Company.

The polymeric compositions of this invention include compositions comprising, or made from, the ethylenic polymer of this invention in combination (such as blends or compounds, including reaction products) with one or more other components, which other components may include, but are not limited to, natural or synthetic materials, polymers, additives, reinforcing agents, ignition resistant additives, fillers, waxes, tackifiers, antioxidants, stabilizers, colorants, extenders, crosslinkers, blowing agents, and/or plasticizers. Such polymeric compositions may include thermoplastic polyolefins (TPO), thermoplastic elastomers (TPE), thermoplastic vulcanizates (TPV) and/or styrenic/ethylenic polymer blends. TPEs and TPVs may be prepared by blending or compounding one or more ethylenic polymers of this invention (including functionalized derivatives thereof) with an optional elastomer (including conventional block copolymers, especially an SBS or SEBS block copolymer, or EPDM, or a natural rubber) and optionally a crosslinking or vulcanizing agent. A TPO polymeric composition of this invention would be prepared by blending or compounding one or more of the ethylenic polymers of this invention with one or more polyolefins (such as polypropylene). A TPE polymeric composition of this invention would be prepared by blending or compounding one or more of the ethylenic polymers of this invention with one or more elastomers (such as a styrenic block copolymer or an olefin block copolymer, such as disclosed in U.S. Pat. No. 7,355,089 (Chang et al.)). A TPV polymeric composition of this invention would be prepared by blending or compounding one or more of the ethylenic polymers of this invention with one or more other polymers and a vulcanizing agent. The foregoing polymeric compositions may be used in forming a molded object, and optionally crosslinking the resulting molded article. A similar procedure using different components has been previously disclosed in U.S. Pat. No. 6,797,779 (Ajbani, et al.).

Processing Aids

In certain aspects of the invention, processing aids, such as plasticizers, can also be included in the polymeric composition. These aids include, but are not limited to, the phthalates (such as dioctyl phthalate and diisobutyl phthalate), natural oils (such as lanolin, and paraffin, naphthenic and aromatic oils obtained from petroleum refining), and liquid resins from rosin or petroleum feedstocks. Exemplary classes of oils useful as processing aids include white mineral oil such as KAYDOL® oil (Chemtura Corp.; Middlebury, Conn.) and SHELLFLEX® 371 naphthenic oil (Shell Lubricants; Houston, Tex.). Another suitable oil is TUFFLO® oil (Lyondell Lubricants; Houston, Tex.).

Stabilizers and Other Additives

In certain aspects of the invention, the ethylenic polymers are treated with one or more stabilizers, for example, antioxidants, such as IRGANOX® 1010 and IRGAFOS® 168 (Ciba Specialty Chemicals; Glattbrugg, Switzerland). In general, polymers are treated with one or more stabilizers before an extrusion or other melt processes. For example, the compounded polymeric composition may comprise from 200 to 600 wppm of one or more phenolic antioxidants, and/or from 800 to 1200 wppm of a phosphite-based antioxidant, and/or from 300 to 1250 wppm of calcium stearate. In other aspects of the invention, other polymeric additives are blended or compounded into the polymeric compositions, such as ultraviolet light absorbers, antistatic agents, pigments, dyes, nucleating agents, fillers, slip agents, fire retardants, plasticizers, processing aids, lubricants, stabilizers, smoke inhibitors, viscosity control agents, and/or anti-blocking agents. The polymeric composition may, for example, comprise less than 10 percent by the combined weight of one or more of such additives, based on the weight of the ethylenic polymer.

Other Additives

Various other additives and adjuvants may be blended or compounded with the ethylenic polymers of this invention to form polymeric compositions, including fillers (such as organic or inorganic particles, including nano-size particles, such as clays, talc, titanium dioxide, zeolites, powdered metals), organic or inorganic fibers (including carbon fibers, silicon nitride fibers, steel wire or mesh, and nylon or polyester cording), tackifiers, waxes, anti-stats, and oil extenders (including paraffinic or naphthelenic oils), sometimes in combination with other natural and/or synthetic polymers.

Cross-Linking Agents

For those end-use applications in which it is desired to fully or partially cross-link the ethylenic polymer of this invention, any of a variety of cross-linking agents may be used. Some suitable cross-linking agents are disclosed in Zweifel Hans et al., “Plastics Additives Handbook,” Hanser Gardner Publications, Cincinnati, Ohio, 5th edition, Chapter 14, pages 725-812 (2001); Encyclopedia of Chemical Technology, Vol. 17, 2nd edition, Interscience Publishers (1968); and Daniel Seem, “Organic Peroxides,” Vol. 1, Wiley-Interscience, (1970). Non-limiting examples of suitable cross-linking agents include peroxides, phenols, azides, aldehyde-amine reaction products, substituted ureas, substituted guanidines; substituted xanthates; substituted dithiocarbamates; sulfur-containing compounds, such as thiazoles, sulfenamides, thiuramidisulfides, paraquinonedioxime, dibenzoparaquinonedioxime, sulfur; imidazoles; silanes and combinations thereof. Non-limiting examples of suitable organic peroxide cross-linking agents include alkyl peroxides, aryl peroxides, peroxyesters, peroxycarbonates, diacylperoxides, peroxyketals, cyclic peroxides and combinations thereof. In some embodiments, the organic peroxide is dicumyl peroxide, t-butylisopropylidene peroxybenzene, 1,1-di-t-butyl peroxy-3,3,5-trimethylcyclohexane, 2,5-dimethyl-2,5-di(t-butyl peroxy) hexane, t-butyl-cumyl peroxide, di-t-butyl peroxide, 2,5-dimethyl-2,5-di-(t-butyl peroxy) hexyne or a combination thereof. In one embodiment, the organic peroxide is dicumyl peroxide. Additional teachings regarding organic peroxide cross-linking agents are disclosed in C. P. Park, “Polyolefin Foam”, Chapter 9 of Handbook of Polymer Foams and Technology, edited by D. Klempner and K. C. Frisch, Hanser Publishers, pp. 198-204, Munich (1991). Non-limiting examples of suitable azide cross-linking agents include azidoformates, such as tetramethylenebis(azidoformate); aromatic polyazides, such as 4,4′-diphenylmethane diazide; and sulfonazides, such as p,p′-oxybis(benzene sulfonyl azide). The disclosure of azide cross-linking agents can be found in U.S. Pat. Nos. 3,284,421 and 3,297,674. In some embodiments, the cross-linking agents are silanes. Any silane that can effectively graft to and/or cross-link the ethylene/α-olefin interpolymer or the polymer blend disclosed herein can be used. Non-limiting examples of suitable silane cross-linking agents include unsaturated silanes that comprise an ethylenically unsaturated hydrocarbyl group, such as a vinyl, allyl, isopropenyl, butenyl, cyclohexenyl or gamma-(meth)acryloxy allyl group, and a hydrolyzable group such as a hydrocarbyloxy, hydrocarbonyloxy, and hydrocarbylamino group. Non-limiting examples of suitable hydrolyzable groups include methoxy, ethoxy, formyloxy, acetoxy, proprionyloxy, alkyl and arylamino groups. In other embodiments, the silanes are the unsaturated alkoxy silanes which can be grafted onto the interpolymer. Some of these silanes and their preparation methods are more fully described in U.S. Pat. No. 5,266,627. The amount of the cross-linking agent can vary widely, depending upon the nature of the ethylenic polymer or the polymeric composition to be cross-linked, the particular cross-linking agent employed, the processing conditions, the amount of grafting initiator, the ultimate application, and other factors. For example, when vinyltrimethoxysilane (VTMOS) is used, the amount of VTMOS is generally at least about 0.1 weight percent, at least about 0.5 weight percent, or at least about 1 weight percent, based on the combined weight of the cross-linking agent and the ethylenic polymer or the polymeric composition.

End Use Applications

The ethylenic polymer of this invention may be employed in a variety of conventional thermoplastic fabrication processes to produce useful articles, including objects comprising at least one film layer, such as a monolayer film, or at least one layer in a multilayer film, which films may be prepared by cast, blown, calendared, or extrusion coating processes; and composite or laminate structures made with any of the foregoing articles.

The ethylenic polymers of this invention (either alone or in blends or compounds with other components) may be used in a variety of films, including but not limited to cast stretch films and sealants (including heat sealing films).

All applications, publications, patents, test procedures, and other documents cited, including priority documents, are fully incorporated by reference to the extent such disclosure is not inconsistent with the disclosed compositions and methods and for all jurisdictions in which such incorporation is permitted.

### EXAMPLES

All raw materials (ethylene, 1-octene) and the process solvent (a narrow boiling range high-purity isoparaffinic solvent trademarked Isopar E and commercially available from Exxon Mobil Corporation) are purified with molecular sieves before introduction into the reaction environment. Hydrogen is supplied in pressurized cylinders as a high purity grade and is not further purified. The reactor monomer feed (ethylene) stream is pressurized via mechanical compressor to above reaction pressure at 525 psig. The solvent and comonomer (1-octene) feed is pressurized via mechanical positive displacement pump to above reaction pressure at 525 psig. The individual catalyst components are manually batch diluted to specified component concentrations with purified solvent (Isopar E) and pressured to above reaction pressure at 525 psig. All reaction feed flows are measured with mass flow meters and independently controlled with computer automated valve control systems.

The continuous solution polymerization reactor consists of a liquid full, non-adiabatic, isothermal, circulating, and independently controlled loop. The reactor has independent control of all fresh solvent, monomer, comonomer, hydrogen, and catalyst component feeds. The combined solvent, monomer, comonomer and hydrogen feed to the reactor is temperature controlled to anywhere between 5° C. to 50° C. and typically 25° C. by passing the feed stream through a heat exchanger. The fresh comonomer feed to the polymerization reactor is fed in with the solvent feed. The total fresh feed to each polymerization reactor is injected into the reactor at two locations with roughly equal reactor volumes between each injection location. The fresh feed is controlled typically with each injector receiving half of the total fresh feed mass flow. The catalyst components are injected into the polymerization reactor through specially designed injection stingers and are each separately injected into the same relative location in the reactor with no contact time prior to the reactor. The primary catalyst component feed is computer controlled to maintain the reactor monomer concentration at a specified target. The two cocatalyst components are fed based on calculated specified molar ratios to the primary catalyst component Immediately following each fresh injection location (either feed or catalyst), the feed streams are mixed with the circulating polymerization reactor contents with Kenics static mixing elements. The contents of each reactor are continuously circulated through heat exchangers responsible for removing much of the heat of reaction and with the temperature of the coolant side responsible for maintaining isothermal reaction environment at the specified temperature. Circulation around each reactor loop is provided by a screw pump.

The effluent from the first polymerization reactor (containing solvent, monomer, comonomer, hydrogen, catalyst components, and molten polymer) exits the first reactor loop and passes through a control valve (responsible for maintaining the pressure of the first reactor at a specified target). As the stream exits the reactor it is contacted with water to stop the reaction. In addition, various additives such as anti-oxidants, can be added at this point. The stream then goes through another set of Kenics static mixing elements to evenly disperse the catalyst kill and additives.

Following additive addition, the effluent (containing solvent, monomer, comonomer, hydrogen, catalyst components, and molten polymer) passes through a heat exchanger to raise the stream temperature in preparation for separation of the polymer from the other lower boiling reaction components. The stream then enters a two stage separation and devolatization system where the polymer is removed from the solvent, hydrogen, and unreacted monomer and comonomer. The recycled stream is purified before entering the reactor again. The separated and devolatized polymer melt is pumped through a die specially designed for underwater pelletization, cut into uniform solid pellets, dried, and transferred into a hopper. After validation of initial polymer properties the solid polymer pellets are manually dumped into a box for storage. Each box typically holds ˜1200 pounds of polymer pellets.

The non-polymer portions removed in the devolatilization step pass through various pieces of equipment which separate most of the ethylene which is removed from the system to a vent destruction unit (it is recycled in manufacturing units). Most of the solvent is recycled back to the reactor after passing through purification beds. This solvent can still have unreacted co-monomer in it that is fortified with fresh co-monomer prior to re-entry to the reactor. This fortification of the co-monomer is an essential part of the product density control method. This recycle solvent can still have some hydrogen which is then fortified with fresh hydrogen to achieve the polymer molecular weight target. A very small amount of solvent leaves the system as a co-product due to solvent carrier in the catalyst streams and a small amount of solvent that is part of commercial grade co-monomers.

Unless otherwise stated, implicit from the context or conventional in the art, all parts and percentages are based on weight.

### Comparative Samples A Through D and Examples 1 Through 4

Eight ethylenic polymers are prepared in order to compare the properties of four ethylene-octene polymers (Comparative Samples A through D) prepared using a known metallocene catalyst to the properties of four ethylene-octene polymers (Examples 1 through 4) that are examples of ethylene interpolymers suited for use according to this invention. Table 1 describes the polymerization conditions used to produce each of the copolymers, with those conditions being set to produce pairs of polymers (e.g., Comparative Sample A and Example 1 are one pair) with comparable melt indices (2) and densities.

TABLE 1

| | | | | | | Reactor | | | Corrected | Reactor | H2 | Octene/ |
|---|---|---|---|---|---|---|---|---|---|---|---|---|
| | | | | MI | | Temp | Solvent/ | C2 | Exit | Poly Conc. | Mole | Olefin |
| Run | Product | Example | Catalyst | (I2) | Density | (° C.) | C2 Ratio | Conv (%) | C2 (g/L) | (Wt %) | % | Ratio |
| 2007C28R04 | 8200 | Comp A | 1301/RIBS2/ | 4.7 | 0.8686 | 120.1 | 4.6 | 86.7 | 15.75 | 24.5 | 0.17 | 47.7 |
| | | | MMAO | | | | | | | | | |
| 2007C28R06 | | 1 | 6114/RIBS2/ | 4.3 | 0.8715 | 190 | 4.79 | 84.8 | 16.06 | 26.4 | 0.32 | 62.3 |
| | | | MMAO | | | | | | | | | |
| 2007C28R01 | 8150 | Comp B | 1301/RIBS2/ | 0.5 | 0.868 | 103 | 6.23 | 83.4 | 16 | 19.6 | — | — |
| | | | MMAO | | | | | | | | | |
| 2007C28R12 | | 2 | 6114/RIBS2/ | 0.5 | 0.8684 | 169.6 | 6.23 | 80.9 | 14.55 | 21.4 | 0.2 | 66.5 |
| | | | MMAO | | | | | | | | | |
| 2007C28R02 | 8100 | Comp C | 1301/RIBS2/ | 1 | 0.87 | 110 | 5.22 | 84.6 | 17 | 22.5 | — | — |
| | | | MMAO | | | | | | | | | |
| 2007C28R10 | | 3 | 6114/RIBS2/ | 0.9 | 0.8709 | 185 | 5.22 | 82.5 | 17.2 | 23.3 | 0.21 | 64.6 |
| | | | MMAO | | | | | | | | | |
| 2007C28R03 | 8452 | Comp D | 1301/RIBS2/ | 3 | 0.875 | 115 | 5.22 | 87.3 | 14 | 22.4 | — | — |
| | | | MMAO | | | | | | | | | |
| 2007C28R11 | | 4 | 6114/RIBS2/ | 2.8 | 0.8764 | 180 | 5.22 | 86.3 | 13.74 | 23.6 | 0.32 | 57.8 |
| | | | MMAO | | | | | | | | | |

CAS name for RIBS-2: Amines, bis(hydrogenated tallow alkyl)methyl, tetrakis(pentafluorophenyl)borate(1-)
CAS name for DOC-6114: Zirconium, [2,2″′-[1,3-propanediylbis(oxy-kO)]bis[3″,5,5″-tris(1,1-dimethylethyl)-5′-methyl[1,1′:3′,1″-terphenyl]-2′-olato-kO]]dimethyl-, (OC-6-33)-
MMAO = modified methyl aluminoxane
CAS numbers for CGC 1301: 199876-48-7 and 200074-30-2

TABLE 2
Summary of properties of Comp A-D and Samples 1-4

| | | | | | | | Vinyl | | | |
|---|---|---|---|---|---|---|---|---|---|---|
| | | Melt Flow | | | | Total | groups/ | Octene | | Sum of |
| | | Ratio | | | | unsaturation | Olefin | mol % by | Vinyls/1000 | unsaturation |
| Sample | Catalyst | I10/I2 | Mw | Mn | Mw/Mn | per 1000 C | groups | C¹³ NMR | carbons | per 100000 C |
| Comp A | 1301/RIBS2/MMAO | 7.7 | 91100 | 37346 | 2.44 | 0.148 | 0.18 | 12.62 | 0.03 | 148 |
| 1 | 6114/RIBS2/MMAO | 7.45 | 92530 | 38376 | 2.41 | 0.122 | 0.52 | 11.65 | 0.06 | I. 122 |
| Comp B | 1301/RIBS2/MMAO | 7.9 | 151250 | 62793 | 2.41 | 0.0825 | 0.17 | 12.64 | 0.01 | 82.5 |
| 2 | 6114/RIBS2/MMAO | 7.98 | 147010 | 66333 | 2.22 | 0.0845 | 0.49 | 14.18 | 0.04 | 84.5 |
| Comp C | 1301/RIBS2/MMAO | 7.6 | 124860 | 52795 | 2.36 | 0.085 | 0.16 | 12.13 | 0.01 | 85 |
| 3 | 6114/RIBS2/MMAO | 8.33 | 126490 | 55977 | 2.26 | 0.118 | 0.52 | 11.85 | 0.06 | 118 |
| Comp D | 1301/RIBS2/MMAO | 7.6 | 93540 | 35174 | 2.66 | 0.114 | 0.18 | 11.09 | 0.02 | 114 |
| 4 | 6114/RIBS2/MMAO | 7.4 | 94390 | 40946 | 2.31 | 0.0835 | 0.58 | 10.48 | 0.05 | 83.5 |

TABLE 3
Details of H¹ NMR data on unsaturations for samples of Tables 1 and 2

| | Structure Name | | | | | | | |
|---|---|---|---|---|---|---|---|---|
| | Vinylene | Vinylene | Internal | Trisubstitute | | Symmetric | Asymmetric | |
| | (trans) | (cis) | Vinylene | (internal) | Vinyl | Vinylidene | Vinylidene | |
| | Structure Code | | | | | | | |
| | Vy1-trans | Vy1-cis | | T3, T4 | | | | |
| | Vy2-trans | Vy2-cis | Vy3 | (mainly T4) | V1 | Vd3 | Vd1 | |
| | Peak position | | | | | | | |
| | | | 5.43 | | 5.04 | | 4.86 | |
| | 5.49 | 5.44 | 5.26 | 5.28-5.18 | 5.90 | 4.80 | 4.81 | |
| | Per | Per | Per | Per | Per | Per | Per | |
| | 1000000 | 1000000 | 1000000 | 1000000 | 1000000 | 1000000 | 1000000 | Example |
| | C's | C's | C's | C's | C's | C's | C's | Number |
| 2007C28R04 | 40.5 | 12.5 | 13.5 | 21.5 | 26 | 27.5 | 6.5 | Comp A |
| 2007C28R06 | 10 | 9 | 0 | 13.5 | 63 | 14.5 | 12 | 1 |
| 2007C28R01 | 30 | 5.5 | 6 | 9.5 | 14 | 14 | 3.5 | Comp B |
| 2007C28R12 | 7.5 | 6 | 0 | 11 | 41.5 | 8 | 10.5 | 2 |
| 2007C28R02 | 31.5 | 6.5 | 6.5 | 8 | 14 | 15.5 | 3 | Comp C |
| 2007C28R10 | 10 | 7.5 | 0 | 12.5 | 61 | 13.5 | 13.5 | 3 |
| 2007C28R03 | 32.5 | 10 | 8 | 15 | 20 | 23.5 | 5 | Comp D |
| 2007C28R11 | 7 | 5.5 | 0 | 8.5 | 48.5 | 7 | 7 | 4 |

### Specific Embodiments

The following prophetic examples 5 and 6 further illustrate the invention. Unless otherwise indicated, all parts and percentages are by weight.

### Example 5

A monolayer 15 mil thick protective film is made from a composition comprising 97 wt % of Sample 1, 3 wt % of vinyl silane, 1.5 wt % of Lupersol® 101, 0.8 wt % of tri-allyl cyanurate, 0.1 wt % of Chimassorb® 944, 0.2 wt % of Naugard® P, and 0.3 wt % of Cyasorb® UV 531. The melt temperature during film formation is kept below about 120° C. to avoid premature crosslinking of the film during extrusion. This film is then used to prepare a solar cell module. One film layer is laminated at a temperature of about 150° C. to a superstrate, e.g., a glass cover sheet, and the front surface of a solar cell, and a second layer then to the back surface of the solar cell and a backskin material, e.g., another glass cover sheet or any other substrate. The protective film is then subjected to conditions that will ensure that the film is substantially crosslinked.

### Formulations and Processing Procedures:

Step 1: Use ZSK-30 extruder with Adhere Screw to compound resin and additive package.

Step 2: Dry the material from Step 2 for 4 hours at 100° F. maximum (use W&C canister dryers).

Step 3: With material hot from dryer, add melted DiCup+Silane+TAC, tumble blend for 15 min and let soak for 4 hours.

TABLE 4
Formulation

| | Example 5 |
|---|---|
| Sample 1 | 94.7 |
| 4-Hydroxy-TEMPO | 0.05 |
| Cyasorb UV 531 | 0.3 |
| Chimassorb 944 LD | 0.1 |
| Tinuvin 622 LD | 0.1 |
| Naugard P | 0.2 |
| Additives below added via soaking step | |
| Dicup-R Peroxide | 2 |
| Gamma-methacrylo-propyl-trimethoxysilane | 1.75 |
| (Dow Corning Z-6030) | |
| Sartomer SR-507 Tri-Allyl Cyanurate (TAC) | 0.8 |
| Total | 100 |

### Test Methods and Results:

The adhesion with glass is measured using silane-treated glass. The procedure of glass treatment is adapted it from a procedure in Gelest, Inc. “Silanes and Silicones, Catalog 3000 A”.

Approximately 10 mL of acetic acid is added to 200 mL of 95% ethanol in order to make the solution slightly acidic. Then, 4 mL of 3-aminopropyltrimethoxysilane is added with stirring, making a ˜2% solution of silane. The solution sits for 5 minutes to allow for hydrolysis to begin, and then it is transferred to a glass dish. Each plate is immersed in the solution for 2 minutes with gentle agitation, removed, rinsed briefly with 95% ethanol to remove excess silane, and allowed to drain. The plates are cured in an oven at 110° C. for 15 minutes. Then, they are soaked in a 5% solution of sodium bicarbonate for 2 minutes in order to convert the acetate salt of the amine to the free amine. They are rinsed with water, wiped dry with a paper towel, and air dried at room temperature overnight.

The method for testing the adhesion strength between the polymer and glass is the 180 peel test. This is not an ASTM standard test, but it is used to examine the adhesion with glass for PV modules. The test sample is prepared by placing uncured film on the top of the glass, and then curing the film under pressure in a compression molding machine. The molded sample is held under laboratory conditions for two days before the test. The adhesion strength is measured with an Instron machine. The loading rate is 2 in/min, and the test is run under ambient conditions. The test is stopped after a stable peel region is observed (about 2 inches). The ratio of peel load over film width is reported as the adhesion strength.

Several important mechanical properties of the cured films are evaluated using tensile and dynamic mechanical analysis (DMA) methods. The tensile test is run under ambient conditions with a load rate of 2 in/min The DMA method is conducted from −100 to 120° C.

The optical properties are determined as follows: Percent of light transmittance is measured by UV-vis spectroscopy. It measures the absorbance in the wavelength of 250 nm to 1200 nm The internal haze is measured using ASTM D1003-61.

The results are reported in Table 5. The EVA is a fully formulated film available from Etimex.

TABLE 5
Test Results

| Key Properties | EVA |
|---|---|
| Elongation to break (%) | 411.7 |
| STDV* | 17.5 |
| Tensile strength at 85° C. (psi) | 51.2 |
| STDV* | 8.9 |
| Elongation to break at 85° C. (%) | 77.1 |
| STDV* | 16.3 |
| Adhesion with glass (N/mm) | 7 |
| % of transmittance | >97 |
| STDV* | 0.1 |
| Internal Haze | 2.8 |
| STDV* | 0.4 |

*STDV = Standard Deviation.

The adhesion with glass is measured using silane-treated glass. The procedure of glass treatment is adapted it from a procedure in Gelest, Inc. “Silanes and Silicones, Catalog 3000 A”:

Approximately 10 mL of acetic acid is added to 200 mL of 95% ethanol in order to make the solution slightly acidic. Then, 4 mL of 3-aminopropyltrimethoxysilane is added with stirring, making a ˜2% solution of silane. The solution sits for 5 minutes to allow for hydrolysis to begin, and then it is transferred to a glass dish. Each plate is immersed in the solution for 2 minutes with gentle agitation, removed, rinsed briefly with 95% ethanol to remove excess silane, and allowed to drain. The plates are cured in an oven at 110° C. for 15 minutes. Then, they are soaked in a 5% solution of sodium bicarbonate for 2 minutes in order to convert the acetate salt of the amine to the free amine. They are rinsed with water, wiped dry with a paper towel, and air dried at room temperature overnight.

The optical properties are determined as follows: Percent of light transmittance is measured by UV-vis spectroscopy. It measures the absorbance in the wavelength of 250 nm to 1200 nm. The internal haze is measured using ASTM D1003-61.

### Example 6

### Copolymer Polyethylene-Based Encapsulant Film

Sample 4 (made by The Dow Chemical Company) is used in this example. There is 100 ppm of antioxidant, Irganox 1076, in the resin. Several additives are selected to add functionality or improve the long term stability of the resin. They are UV absorbent Cyasorb UV 531, UV-stabilizer Chimassorb 944 LD, antioxidant Tinuvin 622 LD, vinyltrimethoxysilane (VTMS), and peroxide Luperox-101. The formulation in weight percent is described in Table 6.

TABLE 6
Film Formulation

| Formulation | Weight Percent |
|---|---|
| Sample 4 | 97.34 |
| Cyasorb UV 531 | 0.3 |
| Chimassorb 944 LD | 0.1 |
| Tinuvin 622 LD | 0.1 |
| Irganox-168 | 0.08 |
| Silane (Dow Corning Z-6300) | 2 |
| Luperox-101 | 0.08 |
| Total | 100 |

### Sample Preparation

Sample 4 pellets are dried at 40° C. for overnight in a dryer. The pellets and the additives are dry mixed and placed in a drum and tumbled for 30 minutes. Then the silane and peroxide are poured into the drum and tumbled for another 15 minutes. The well-mixed materials are fed to a film extruder for film casting.

Film is cast on a film line (single screw extruder, 24-inch width sheet die) and the processing conditions are summarized in Table 7.

TABLE 7
Process Conditions

| | | | Extruder Die | | | | | | |
|---|---|---|---|---|---|---|---|---|---|
| Example | | | Head P | Zone | Zone | Zone | Adapter | Adapter | Die |
| # | RPM | Amp | (psi) | 1 (F.) | 2 (F.) | 3 (F.) | (F.) | (C.) | (C.) |
| 8 | 25 | 22 | 2,940 | 300 | 325 | 350 | 350 | 182 | 140 |

An 18-19 mil thick film is saved at 5.3 feet per minute (ft/min) The film sample is sealed in an aluminum bag to avoid UV-irradiation and moisture.

Test Methods and Results

1. Optical Property:

The light transmittance of the film is examined by UV-visible spectrometer (Perkin Elmer UV-Vis 950 with scanning double monochromator and integrating sphere accessory). Samples used for this analysis have a thickness of 15 mils

2. Adhesion to Glass:

The method used for the adhesion test is a 180° peel test. This is not an ASTM standard test, but has been used to examine the adhesion with glass for photovoltaic module and auto laminate glass applications. The test sample is prepared by placing the film on the top of glass under pressure in a compression molding machine. The desired adhesion width is 1.0 inch. The frame used to hold the sample is 5 inches by 5 inches. A Teflon™ sheet is placed between the glass and the material to separate the glass and polymer for the purpose of test setup. The conditions for the glass/film sample preparation are:
(1) 160° C. for 3 minutes at 80 pounds per square inch (psi) (2000 lbs)
(2) 160° C. for 30 minutes at 320 psi (8000 lbs)
(3) Cool to room temperature at 320 psi (8000 lbs)
(4) Remove the sample from the chase and allow 48 hours for the material to condition at room temperature before the adhesion test.

The adhesion strength is measured with a materials testing system (Instron 5581). The loading rate is 2 inches/minutes and the tests are run at ambient conditions (24° C. and 50% RH). A stable peel region is needed (about 2 inches) to evaluate the adhesion to glass. The ratio of peel load in the stable peel region over the film width is reported as the adhesion strength.

The effect of temperature and moisture on adhesion strength is examined using samples aged in hot water (80° C.) for one week. These samples are molded on glass, then immersed in hot water for one week. These samples are then dried under laboratory conditions for two days before the adhesion test. In comparison, the adhesion strength of the same commercial EVA film as described above is also evaluated under the same conditions. The adhesion strength of the experimental film and the commercial sample are shown in Table 8.

TABLE 8
Tests Results of Adhesion to Glass

| | Conditions | | Adhesion |
|---|---|---|---|
| Sample | for Molding | Aging | Strength |
| Information | on Glass | Condition | (N/mm) |
| Commercial Film | 160° C., one hr | None | 10 |
| (cured) | | | |
| Commercial Film | 160° C., one hr | 80° C. in water | |
| (cured) | | for one week | 1 |

3. Water Vapor Transmission Rate (WVTR):

The water vapor transmission rate is measured using a permeation analysis instrument (Mocon Permatran W Model 101 K). All WVTR units are in grams per square meter per day (g/(m²-day) measured at 38° C. and 50° C. and 100% RH, an average of two specimens. The commercial EVA film as described above is also tested to compare the moisture barrier properties. The inventive film and the commercial are cured at 160° C. for 30 minutes. The results of WVTR testing are reported in Table 9.

TABLE 9
Summary of WVTR Test Results

| | | | | Permeation | Permeation |
|---|---|---|---|---|---|
| | WVTR at | WVTR at | Thick | at 38 C. | at 50 C. |
| | 38 C. g/ | 50 C. g/ | (mil) | (g-mil)/ | (g-mil)/ |
| | (m²-day) | (m²-day) | mil | (m²-day) | (m²-day) |
| Commercial | 367.4 | 821.5 | 14 | 5143.6 | 11501 |
| EVA Film | | | | | |
| Example 5 | 49.6 | 117.8 | 15 | 744 | 1767 |
| Film | | | | | |

Two set of samples are prepared to demonstrate that UV absorption can be shifted by using different UV-stabilizers. Example 3 polyolefin elastomer (“POE 3”, density 0.87 g/cc, melt index 0.9), are used and Table 10 reports the formulations with different UV-stabilizers (all amounts are in weight percent). The samples are made using a mixer at a temperature of 190° C. for 5 minutes. Thin films with a thickness of 16 mils are made using a compressing molding machine. The molding conditions are 10 minutes at 160° C., and then cooling to 24° C. in 30 minutes. The UV spectrum is measured using a UV/Vis spectrometer such as a Lambda 950. The results show that different types (and/or combinations) of UV-stabilizers can allow the absorption of UV radiation at a wavelength below 360 nm

TABLE 10
Different UV-Stabilizers

| | POE | Absorber | Cyasorb | Cyasorb | Chimassorb | Chimassorb | Tinuvin |
|---|---|---|---|---|---|---|---|
| Sample | 3 | UV-531 | UV2908 | UV3529 | UV-119 | 944-LD | 622-LD |
| 1 | 100 | | | | | | |
| 2 | 99.7 | 0.3 | | | | | |
| 3 | 99.7 | | 0.3 | | | | |
| 4 | 99.7 | | | 0.3 | | | |
| 5 | 99.7 | | | | 0.3 | | |
| 6 | 99.5 | | | | | 0.25 | 0.25 |
| 7 | 99.85 | 0.15 | | | | | |

Another set of samples are prepared to examine UV-stability. Again, a polyolefin elastomer, Example 4 (“POE 4”) is selected for this study. Table 11 reports the formulations designed for encapsulant polymers for photovoltaic modules with different UV-stabilizers, silane and peroxide, and antioxidant. These formulations are designed to lower the UV absorbance and at the same time maintain and improved the long term UV-stability.

TABLE 11
Different UV-Stabilizers, Silanes, Peroxides and Antioxidants

| | | | Cyasorb | Cyasorb | | | | | | | | |
|---|---|---|---|---|---|---|---|---|---|---|---|---|
| | | Absorber | UV | UV | Univil | Doverphos | Hostavin | Chimassorb | Chimassorb | Tinuvin | Western | Irgafos |
| Samples | POE4 | UV 531 | 2908 | 3529 | 4050 | S-9228 | N30 | UV 119 | 944 LD | 622 LD | 399 | 166 |
| C 1 | 99.8 | | | | | | | | | | 0.2 | |
| C 2 | 99.3 | 0.3 | | | | | | | 0.1 | 0.1 | 0.2 | |
| C 3 | 99.5 | 0.3 | | | | | | | 0.1 | 0.1 | | |
| 1 | 99.5 | | 0.5 | | | | | | | | | |
| 2 | 99.5 | | | 0.5 | | | | | | | | |
| 3 | 99.5 | | | | | | | 0.5 | | | | |
| 4 | 99.5 | | | | | | | | 0.5 | | | |
| 5 | 99.7 | | | 0.3 | | | | | | 0.5 | | |
| 6 | 99.3 | | | 0.7 | | | | | | | | |
| 7 | 99.5 | | | | 0.5 | | | | | | | |
| 8 | 99.5 | | | | | | 0.5 | | | | | |
| 9 | 99.4 | 0.3 | | | | 0.1 | | | 0.1 | 0.1 | | |
| 10 | 99.3 | 0.3 | | | | | | | 0.1 | 0.1 | | 0.2 |
| 11 | 99.3 | | | 0.5 | | | | | | | | 0.2 |

### Experiment 7

The following experiment further illustrates the invention. Unless otherwise indicated, all parts and percentages are by weight. Generally as disclosed for Sample 5 above, an ethylene interpolymer is used having: a. an overall polymer density of not more than 0.905 g/cm³; b. total unsaturation of not more than 125 per 100,000 carbons; c. up to 3 long chain branches/1000 carbons; d. vinyl-3 content of less than 5 per 100,000 carbons; and e. a total number of vinyl groups/1000 carbons of less than the quantity (8000/Mₙ), wherein the vinyl-3 content and vinyl group measurements are measured by gel permeation chromatography (145° C.) and ¹H-NMR (125° C.). The ethylene interpolymer is commercially available as ENGAGE 8200 with a target melt index of 5.0 (ASTM D1238 190 C 2.16 kg) and target density of 0.8700 (ASTM D4703, A1 Procedure C, test within 1 hour), is produced generally as described in Example 1 above. The ethylene interpolymer is then used to produce a film with a final vinyl silane content of 1.6% by weight and comprising Cyasorb 2908 and Cyasorb 3529. This film is produced by standard cast extrusion on a film line (single screw extruder, 9-inch width sheet die) and using the processing conditions as summarized in Table 12.

TABLE 12

| | | | Extruder Die | | | | | | |
|---|---|---|---|---|---|---|---|---|---|
| | | | Head | | | | | | |
| | | | Pressure | Zone | Zone | Zone | Adapter | Adapter | Die |
| Expt # | RPM | Amp | (psi) | 1 (F.) | 2 (F.) | 3 (F.) | (F.) | (C.) | (C.) |
| 7 | 30 | 4 | 870 | 325 | 350 | 370 | 375 | 190 | 199 |

An 18-19 mil thick film is saved at 3.8 feet per minute (ft/min). The film sample is sealed in an aluminum bag to avoid UV-irradiation and moisture.

Test Methods and Results

1. Optical Property: The light transmittance of the film is examined by UV-visible spectrometer (Perkin Elmer UV-Vis 950 with scanning double monochromator and integrating sphere accessory). Samples used for this analysis have a thickness of 18 mils The results are shown in Table 13, below.

2. Adhesion to Glass: The method used for the adhesion test is a 180° peel test. This is not an ASTM standard test, but has been used to examine the adhesion with glass for photovoltaic module and auto laminate glass applications. The test sample is prepared by placing the film on the top of untreated glass under pressure in a vacuum laminator. The desired adhesion width is 1.0 inch. A 4 inch by 6 inch test coupon is made, to allow for 3 peels to be made from the center portion of the glass, eliminating edge effects. A Teflon™ sheet is placed between the glass and the material to separate the glass and polymer for the purpose of test setup. A standard polymer backsheet (Tedlar-polyester-EVA construction) is used on the top surface of the coupon to provide rigidity to the encapsulant for the purpose of the peel test. This prevents the film from stretching during the test, and provides a more accurate peel force value. The conditions for the glass/film sample preparation are:
(1) 150° C. for 3 minutes at >990 mBar vacuum
(2) 150° C. for 7 minutes at 1000 mBar pressure
(3) Remove the sample from the laminator and allow to cool to room temperature before the adhesion test.

The adhesion strength is measured with a materials testing system (Instron 5581) and reported in Table 13, below. The loading rate is 2 inches/minutes and the tests are run at ambient conditions (24° C. and 50% RH). A stable peel region is needed (about 2 inches) to evaluate the adhesion to glass. The ratio of peel load in the stable peel region over the film width is reported as the adhesion strength.

TABLE 13

| | Adhesion to Glass | % Transmission | | |
|---|---|---|---|---|
| Film | Average (lb/in) | 400 nm | 600 nm | 900 nm |
| Expt 7 | 80 | 86.4 | 90.7 | 93.4 |

This shows good adhesion and bonding to glass and light transmission properties.

Although the invention has been described in considerable detail through the preceding description and examples, this detail is for the purpose of illustration and is not to be construed as a limitation on the scope of the invention as it is described in the appended claims. All United States patents, published patent applications and allowed patent applications identified above are incorporated herein by reference.

What is claimed is:

1. An electronic device module comprising:
A. at least one electronic device, and
B. a polymeric material in intimate contact with at least one surface of the electronic device, the polymeric material comprising:
(1) an ethylene interpolymer having:
a. an overall polymer density of not more than 0.905 g/cm³;
b. total unsaturation of not more than 125 per 100,000 carbons;
c. up to 3 long chain branches/1000 carbons;
d. vinyl-3 content of less than 5 per 100,000 carbons; and
e. a total number of vinyl groups/1000 carbons of less than the quantity (8000/Mₙ),
wherein the vinyl-3 content and vinyl group measurements are measured by gel permeation chromatography (145° C.) and ¹H-NMR (125° C.),
(2) grafted silane,
(3) optionally, free radical initiator or a photoinitiator in an amount of at least about 0.05 wt % based on the weight of the interpolymer, and
(4) optionally, a co-agent in an amount of at least about 0.05 wt % based upon the weight of the interpolymer.

2. The module of claim 1 in which the electronic device is a solar cell.

3. The module of claim 1 in which the free radical initiator is present.

4. The module of claim 3 in which the coagent is present.

5. The module of claim 4 in which the free radical initiator is a peroxide.

6. The module of claim 1 in which the polymeric material is in the form of a monolayer film in intimate contact with at least one face surface of the electronic device.

7. The module of claim 1 in which the polymeric material further comprises a scorch inhibitor in an amount from about 0.01 to about 1.7 wt %.

8. The module of claim 1 further comprising at least one glass cover sheet.

9. The module of claim 3 in which the free radical initiator is a photoinitiator.

10. The module of claim 1 which the grafted vinyl silane is grafted to the ethylene interpolymer.

11. The module of claim 1 in which the grafted vinyl silane is grafted to a separate compatible graft polymer and is added to the ethylene interpolymer of the polymeric material.

12. The module of claim 1 in which the vinyl silane is at least one of vinyl tri-ethoxy silane and vinyl tri-methoxy silane.

13. The module of claim 1 in which the free radical initiator is a peroxide.

14. The module of claim 1 in which the co-agent is present.

15. The module of claim 1 in which the polyolefin copolymer is crosslinked such that the copolymer contains less than about 85 percent xylene soluble extractables as measured by ASTM 2765-95.
